(19) United States
(12) Patent Application Publication
(10) Pub. No.: US 2013/0100090 A1
(43) Pub. Date: Apr. 25, 2013

(54) ELECTROMECHANICAL SYSTEMS VARIABLE CAPACITANCE DEVICE

(71) Applicants: Daniel FELNHOFER, San Jose, CA (US); Wenyue ZHANG, San Jose, CA (US); Je-Hsuing LAN, San Diego, CA (US)

(72) Inventors: Daniel FELNHOFER, San Jose, CA (US); Wenyue ZHANG, San Jose, CA (US); Je-Hsuing LAN, San Diego, CA (US)

(73) Assignee: QUALCOMM MEMS TECHNOLOGIES, INC., San Diego, CA (US)

(21) Appl. No.: 13/279,089

(22) Filed: Oct. 21, 2011

(51) Int. Cl. G09G 5/00; H01L 21/329; H01L 29/93

(52) U.S. Cl. 345/204; 257/602; 438/379; 257/E29.344; 257/E21.364

(57) ABSTRACT

This disclosure provides systems, methods and apparatus for electromechanical systems variable capacitance devices. In one aspect, an electromechanical systems variable capacitance device includes a substrate with a first metal layer including a first bias electrode overlying the substrate. A member suspended above the first metal layer includes a dielectric beam and a second metal layer including a first radio frequency electrode and a ground electrode. The member and the first metal layer define a first air gap. A third metal layer over the member includes a second bias electrode, and the third metal layer and the member define a second air gap. The member includes a plane of symmetry substantially parallel a plane containing the first bias electrode.

### TECHNICAL FIELD

This disclosure relates generally to electromechanical systems (EMS) devices and more particularly to EMS variable capacitance devices.

### DESCRIPTION OF THE RELATED TECHNOLOGY

Electromechanical systems include devices having electrical and mechanical elements, actuators, transducers, sensors, optical components (e.g., mirrors) and electronics. Electromechanical systems can be manufactured at a variety of scales including, but not limited to, microscales and nanoscales. For example, microelectromechanical systems (MEMS) devices can include structures having sizes ranging from about a micron to hundreds of microns or more. Nanoelectromechanical systems (NEMS) devices can include structures having sizes smaller than a micron including, for example, sizes smaller than several hundred nanometers. Electromechanical elements may be created using deposition, etching, lithography, and/or other micromachining processes that etch away parts of substrates and/or deposited material layers, or that add layers to form electrical and electromechanical devices.

One type of electromechanical systems device is called an interferometric modulator (IMOD). As used herein, the term interferometric modulator or interferometric light modulator refers to a device that selectively absorbs and/or reflects light using the principles of optical interference. In some implementations, an interferometric modulator may include a pair of conductive plates, one or both of which may be transparent and/or reflective, wholly or in part, and capable of relative motion upon application of an appropriate electrical signal. In an implementation, one plate may include a stationary layer deposited on a substrate and the other plate may include a reflective membrane separated from the stationary layer by an air gap. The position of one plate in relation to another can change the optical interference of light incident on the interferometric modulator. Interferometric modulator devices have a wide range of applications, and are anticipated to be used in improving existing products and creating new products, especially those with display capabilities.

EMS devices also may be used to implement various radio frequency (RF) circuit components. For example, another type of EMS device is an EMS variable capacitance device, also referred to as an EMS varactor. An EMS varactor may be included in various circuits such as tunable filters, tunable antennas, etc.

### SUMMARY

The systems, methods and devices of the disclosure each have several innovative aspects, no single one of which is solely responsible for the desirable attributes disclosed herein.

One innovative aspect of the subject matter described in this disclosure can be implemented in an electromechanical systems varactor. An electromechanical systems varactor may include a substrate having a first metal layer overlying the substrate. The first metal layer may include a first bias electrode. A member may be suspended over the first metal layer, with the member and the first metal layer defining a first air gap. The member may include a dielectric beam and a second metal layer. The second metal layer may include a first radio frequency electrode and a ground electrode. A third metal layer may be over the member, with the third metal layer and the member defining a second air gap. The third metal layer may include a second bias electrode. The member may include a plane of symmetry substantially parallel a plane containing the first bias electrode.

In some implementations, the second metal layer of the member may be embedded in the dielectric beam of the member. In some other implementations, the first radio frequency electrode may include a first layer and a second layer and the ground electrode may include a first layer and a second layer. The first layer of the first radio frequency electrode and the first layer of the ground electrode may be exposed to the first air gap. The second layer of the first radio frequency electrode and the second layer of the ground electrode may be exposed to the second air gap. The first layer and the second layer of the first radio frequency electrode may be coupled to each other by a first conductive material filling a first via through the dielectric beam. The first layer and the second layer of the ground electrode may be coupled to each other by a second conductive material filling a second via through the dielectric beam.

In some implementations, the member may be configured to mechanically move into the first air gap in response to a first direct current voltage received by the first bias electrode, and the member may be configured to mechanically move into the second air gap in response to a second direct current voltage received by the second bias electrode.

Another innovative aspect of the subject matter described in this disclosure can be implemented in an electromechanical systems varactor. An electromechanical systems varactor may include a substrate having a first metal layer overlying the substrate. The first metal layer may include a first bias electrode. A member may be suspended over the first metal layer. The member may include a dielectric beam and a second metal layer. The second metal layer may include a first radio frequency electrode and a ground electrode, with the first radio frequency electrode and the ground electrode being electrically isolated from each other. A third metal layer may be over the member. The third metal layer may include a second bias electrode. The member may include a plane of symmetry substantially parallel a plane containing the first bias electrode.

In some implementations, the second metal layer of the member may be embedded in the dielectric beam of the member. In some other implementations, the first radio frequency electrode may include a first layer and a second layer and the ground electrode may include a first layer and a second layer. The first layer of the first radio frequency electrode and the first layer of the ground electrode may be exposed to the first air gap. The second layer of the first radio frequency electrode and the second layer of the ground electrode may be exposed to the second air gap. The first layer and the second layer of the first radio frequency electrode may be coupled to each other by a first conductive material filling a first via through the dielectric beam. The first layer and the second layer of the ground electrode may be coupled to each other by a second conductive material filling a second via through the dielectric beam.

Another innovative aspect of the subject matter described in this disclosure can be implemented in a method of fabricating an electromechanical systems varactor. A first metal layer may be formed on a substrate. A first sacrificial layer may be formed on the first metal layer. A member may be formed on the first sacrificial layer, with the member including a dielectric beam, a first radio frequency electrode, and a ground electrode. A second sacrificial layer may be formed on the member. A second metal layer may be formed on the second sacrificial layer. The first and the second sacrificial layers may be removed. The dielectric beam, the first radio frequency electrode, and the ground electrode may include a plane of symmetry substantially parallel to a plane containing the first metal layer.

In some implementations, a member may be formed by forming a first dielectric layer on the first sacrificial layer. A third metal layer may be formed on the first dielectric layer. The first radio frequency electrode and the ground electrode may be formed from the third metal layer. A second dielectric layer may be formed on the third metal layer. The first dielectric layer and the second dielectric layer may form the dielectric beam.

In some other implementations, a member may be formed by forming a third metal layer on the first sacrificial layer. A bottom layer of the first radio frequency electrode and a bottom layer of the ground electrode may be formed from the third metal layer. A dielectric layer may be formed on the third metal layer. First vias and second vias may be etched in the dielectric layer. A fourth metal layer may be formed on the dielectric layer, including filling the first vias and second vias with the fourth metal layer. A top layer of the first radio frequency electrode and a top layer of the ground electrode may be formed from the fourth metal layer. The first vias may couple the bottom layer and the top layer of the first radio frequency electrode. The second vias may couple the bottom layer and the top layer of the ground electrode. The dielectric layer may form the dielectric beam.

Details of one or more implementations of the subject matter described in this specification are set forth in the accompanying drawings and the description below. Other features, aspects, and advantages will become apparent from the description, the drawings, and the claims. Note that the relative dimensions of the following figures may not be drawn to scale.

### BRIEF DESCRIPTION OF THE DRAWINGS

FIG. 1 shows an example of an isometric view depicting two adjacent pixels in a series of pixels of an interferometric modulator (IMOD) display device.

FIG. 2 shows an example of a system block diagram illustrating an electronic device incorporating a 3×3 interferometric modulator display.

FIG. 3 shows an example of a diagram illustrating movable reflective layer position versus applied voltage for the interferometric modulator of FIG. 1.

FIG. 4 shows an example of a table illustrating various states of an interferometric modulator when various common and segment voltages are applied.

FIG. 5A shows an example of a diagram illustrating a frame of display data in the 3×3 interferometric modulator display of FIG. 2.

FIG. 5B shows an example of a timing diagram for common and segment signals that may be used to write the frame of display data illustrated in FIG. 5A.

FIG. 6A shows an example of a partial cross-section of the interferometric modulator display of FIG. 1.

FIGS. 6B-6E show examples of cross-sections of varying implementations of interferometric modulators.

FIG. 7 shows an example of a flow diagram illustrating a manufacturing process for an interferometric modulator.

FIGS. 8A-8E show examples of cross-sectional schematic illustrations of various stages in a method of making an interferometric modulator.

FIGS. 9 and 10 show examples of schematic illustrations of an EMS varactor.

FIG. 11 shows an example of a top-down schematic illustration of a portion of the member of the EMS varactor shown in FIGS. 9 and 10.

FIG. 12 shows an example of a cross-sectional schematic illustration of an EMS varactor.

FIGS. 13A-13E show examples of cross-sectional schematic illustrations of EMS varactors.

FIG. 14 shows an example of a flow diagram illustrating a manufacturing process for an EMS varactor.

FIGS. 15A and 15B show examples of flow diagrams illustrating manufacturing processes for a member of an EMS varactor.

FIGS. 16A and 16B show examples of system block diagrams illustrating a display device that includes a plurality of interferometric modulators.

Like reference numbers and designations in the various drawings indicate like elements.

### DETAILED DESCRIPTION

The following detailed description is directed to certain implementations for the purposes of describing the innovative aspects. However, the teachings herein can be applied in a multitude of different ways. The described implementations may be implemented in any device that is configured to display an image, whether in motion (e.g., video) or stationary (e.g., still image), and whether textual, graphical or pictorial. More particularly, it is contemplated that the implementations may be implemented in or associated with a variety of electronic devices such as, but not limited to, mobile telephones, multimedia Internet enabled cellular telephones, mobile television receivers, wireless devices, smartphones, bluetooth devices, personal data assistants (PDAs), wireless electronic mail receivers, hand-held or portable computers, netbooks, notebooks, smartbooks, tablets, printers, copiers, scanners, facsimile devices, GPS receivers/navigators, cameras, MP3 players, camcorders, game consoles, wrist watches, clocks, calculators, television monitors, flat panel displays, electronic reading devices (e.g., e-readers), computer monitors, auto displays (e.g., odometer display, etc.), cockpit controls and/or displays, camera view displays (e.g., display of a rear view camera in a vehicle), electronic photographs, electronic billboards or signs, projectors, architectural structures, microwaves, refrigerators, stereo systems, cassette recorders or players, DVD players, CD players, VCRs, radios, portable memory chips, washers, dryers, washer/dryers, parking meters, packaging (e.g., electromechanical systems (EMS), MEMS and non-MEMS), aesthetic structures (e.g., display of images on a piece of jewelry) and a variety of electromechanical systems devices. The teachings herein also can be used in non-display applications such as, but not limited to, electronic switching devices, radio frequency filters, sensors, accelerometers, gyroscopes, motion-sensing devices, magnetometers, inertial components for consumer electronics, parts of consumer electronics products, varactors, liquid crystal devices, electrophoretic devices, drive schemes, manufacturing processes, electronic test equipment. Thus, the teachings are not intended to be limited to the implementations depicted solely in the Figures, but instead have wide applicability as will be readily apparent to one having ordinary skill in the art.

Some implementations described herein relate to EMS variable capacitance devices or EMS varactors. EMS varactors may incorporate a number of metal layers over a substrate. One metal layer may include a first RF electrode, and a second metal layer may include a second RF electrode, with the first RF electrode and the second RF electrode defining an air gap. Bias electrodes may be used to tune the capacitance of an EMS varactor by applying a direct current (DC) voltage to a bias electrode. This may cause the air gap to collapse or expand, which can change the capacitance of the EMS varactor.

For example, in some implementations described herein, an EMS varactor may include a substrate with a first metal layer overlying the substrate. The first metal layer may include a first bias electrode and a first RF electrode. A member may be suspended over the first metal layer. The member may include a dielectric beam and a second metal layer, with the member and the first metal layer defining a first air gap. The second metal layer may include a second RF electrode and a ground electrode. A third metal layer may be over the member, with the third metal layer including a second bias electrode. The third metal layer and the member may define a second air gap. The member may include a plane of symmetry substantially parallel to a plane containing the first bias electrode. The second RF electrode may be configured to mechanically move in response to a first DC voltage received by the first bias electrode and to mechanically move in response to a second DC voltage received by the second bias electrode. With the second RF electrode configured to move, a capacitance between the first RF electrode and the second RF electrode may be variable.

Particular implementations of the subject matter described in this disclosure can be implemented to realize one or more of the following potential advantages. In the EMS varactor designs disclosed herein, a member may include a bias electrode and a RF electrode which may be a dedicated bias electrode and a dedicated RF electrode, respectively. That is, a bias electrode may receive a DC voltage and not both a DC voltage and a RF signal. A RF electrode may receive a RF signal and not both a RF signal and a DC voltage. A member of a varactor including a bias electrode and a RF electrode thus may have separate DC and RF paths. Separate DC and RF paths for a member in a varactor may reduce the interference and the coupling of these two inputs. A dielectric layer in the member also may improve the mechanical performance, such as the fatigue properties and the thermal stability, of the EMS varactor. Further, with such a member, a three-layer, five-terminal EMS varactor may be fabricated.

An example of a suitable electromechanical systems (EMS) or MEMS device, to which the described implementations may apply, is a reflective display device. Reflective display devices can incorporate interferometric modulators (IMODs) to selectively absorb and/or reflect light incident thereon using principles of optical interference. IMODs can include an absorber, a reflector that is movable with respect to the absorber, and an optical resonant cavity defined between the absorber and the reflector. The reflector can be moved to two or more different positions, which can change the size of the optical resonant cavity and thereby affect the reflectance of the interferometric modulator. The reflectance spectrums of IMODs can create fairly broad spectral bands which can be shifted across the visible wavelengths to generate different colors. The position of the spectral band can be adjusted by changing the thickness of the optical resonant cavity, i.e., by changing the position of the reflector.

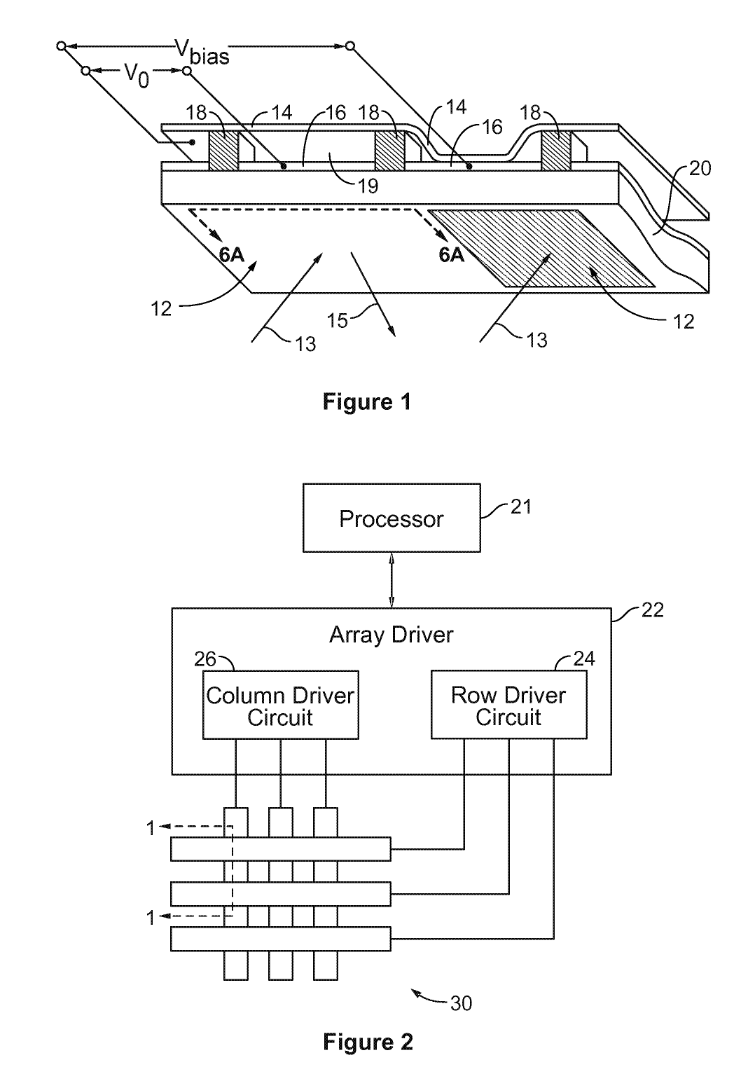

FIG. 1 shows an example of an isometric view depicting two adjacent pixels in a series of pixels of an interferometric modulator (IMOD) display device. The IMOD display device includes one or more interferometric MEMS display elements. In these devices, the pixels of the MEMS display elements can be in either a bright or dark state. In the bright (“relaxed,” “open” or “on”) state, the display element reflects a large portion of incident visible light, e.g., to a user. Conversely, in the dark (“actuated,” “closed” or “off”) state, the display element reflects little incident visible light. In some implementations, the light reflectance properties of the on and off states may be reversed. MEMS pixels can be configured to reflect predominantly at particular wavelengths allowing for a color display in addition to black and white.

The IMOD display device can include a row/column array of IMODs. Each IMOD can include a pair of reflective layers, i.e., a movable reflective layer and a fixed partially reflective layer, positioned at a variable and controllable distance from each other to form an air gap (also referred to as an optical gap or cavity). The movable reflective layer may be moved between at least two positions. In a first position, i.e., a relaxed position, the movable reflective layer can be positioned at a relatively large distance from the fixed partially reflective layer. In a second position, i.e., an actuated position, the movable reflective layer can be positioned more closely to the partially reflective layer. Incident light that reflects from the two layers can interfere constructively or destructively depending on the position of the movable reflective layer, producing either an overall reflective or non-reflective state for each pixel. In some implementations, the IMOD may be in a reflective state when unactuated, reflecting light within the visible spectrum, and may be in a dark state when unactuated, reflecting light outside of the visible range (e.g., infrared light). In some other implementations, however, an IMOD may be in a dark state when unactuated, and in a reflective state when actuated. In some implementations, the introduction of an applied voltage can drive the pixels to change states. In some other implementations, an applied charge can drive the pixels to change states.

The depicted portion of the pixel array in FIG. 1 includes two adjacent interferometric modulators 12. In the IMOD 12 on the left (as illustrated), a movable reflective layer 14 is illustrated in a relaxed position at a predetermined distance from an optical stack 16, which includes a partially reflective layer. The voltage V₀ applied across the IMOD 12 on the left is insufficient to cause actuation of the movable reflective layer 14. In the IMOD 12 on the right, the movable reflective layer 14 is illustrated in an actuated position near or adjacent the optical stack 16. The voltage V_{bias} applied across the IMOD 12 on the right is sufficient to maintain the movable reflective layer 14 in the actuated position.

In FIG. 1, the reflective properties of pixels 12 are generally illustrated with arrows 13 indicating light incident upon the pixels 12, and light 15 reflecting from the IMOD 12 on the left. Although not illustrated in detail, it will be understood by one having ordinary skill in the art that most of the light 13 incident upon the pixels 12 will be transmitted through the transparent substrate 20, toward the optical stack 16. A portion of the light incident upon the optical stack 16 will be transmitted through the partially reflective layer of the optical stack 16, and a portion will be reflected back through the transparent substrate 20. The portion of light 13 that is transmitted through the optical stack 16 will be reflected at the movable reflective layer 14, back toward (and through) the transparent substrate 20. Interference (constructive or destructive) between the light reflected from the partially reflective layer of the optical stack 16 and the light reflected from the movable reflective layer 14 will determine the wavelength(s) of light 15 reflected from the IMOD 12.

The optical stack 16 can include a single layer or several layers. The layer(s) can include one or more of an electrode layer, a partially reflective and partially transmissive layer and a transparent dielectric layer. In some implementations, the optical stack 16 is electrically conductive, partially transparent and partially reflective, and may be fabricated, for example, by depositing one or more of the above layers onto a transparent substrate 20. The electrode layer can be formed from a variety of materials, such as various metals, for example indium tin oxide (ITO). The partially reflective layer can be formed from a variety of materials that are partially reflective, such as various metals, e.g., chromium (Cr), semiconductors, and dielectrics. The partially reflective layer can be formed of one or more layers of materials, and each of the layers can be formed of a single material or a combination of materials. In some implementations, the optical stack 16 can include a single semi-transparent thickness of metal or semiconductor which serves as both an optical absorber and conductor, while different, more conductive layers or portions (e.g., of the optical stack 16 or of other structures of the IMOD) can serve to bus signals between IMOD pixels. The optical stack 16 also can include one or more insulating or dielectric layers covering one or more conductive layers or a conductive/absorptive layer.

In some implementations, the layer(s) of the optical stack 16 can be patterned into parallel strips, and may form row electrodes in a display device as described further below. As will be understood by one having skill in the art, the term “patterned” is used herein to refer to masking as well as etching processes. In some implementations, a highly conductive and reflective material, such as aluminum (Al), may be used for the movable reflective layer 14, and these strips may form column electrodes in a display device. The movable reflective layer 14 may be formed as a series of parallel strips of a deposited metal layer or layers (orthogonal to the row electrodes of the optical stack 16) to form columns deposited on top of posts 18 and an intervening sacrificial material deposited between the posts 18. When the sacrificial material is etched away, a defined gap 19, or optical cavity, can be formed between the movable reflective layer 14 and the optical stack 16. In some implementations, the spacing between posts 18 may be approximately 1-1000 um, while the gap 19 may be less than 10,000 Angstroms (Å).

In some implementations, each pixel of the IMOD, whether in the actuated or relaxed state, is essentially a capacitor formed by the fixed and moving reflective layers. When no voltage is applied, the movable reflective layer 14 remains in a mechanically relaxed state, as illustrated by the IMOD 12 on the left in FIG. 1, with the gap 19 between the movable reflective layer 14 and optical stack 16. However, when a potential difference, e.g., voltage, is applied to at least one of a selected row and column, the capacitor formed at the intersection of the row and column electrodes at the corresponding pixel becomes charged, and electrostatic forces pull the electrodes together. If the applied voltage exceeds a threshold, the movable reflective layer 14 can deform and move near or against the optical stack 16. A dielectric layer (not shown) within the optical stack 16 may prevent shorting and control the separation distance between the layers 14 and 16, as illustrated by the actuated IMOD 12 on the right in FIG. 1. The behavior is the same regardless of the polarity of the applied potential difference. Though a series of pixels in an array may be referred to in some instances as “rows” or “columns,” a person having ordinary skill in the art will readily understand that referring to one direction as a “row” and another as a “column” is arbitrary. Restated, in some orientations, the rows can be considered columns, and the columns considered to be rows. Furthermore, the display elements may be evenly arranged in orthogonal rows and columns (an “array”), or arranged in non-linear configurations, for example, having certain positional offsets with respect to one another (a “mosaic”). The terms “array” and “mosaic” may refer to either configuration. Thus, although the display is referred to as including an “array” or “mosaic,” the elements themselves need not be arranged orthogonally to one another, or disposed in an even distribution, in any instance, but may include arrangements having asymmetric shapes and unevenly distributed elements.

FIG. 2 shows an example of a system block diagram illustrating an electronic device incorporating a 3×3 interferometric modulator display. The electronic device includes a processor 21 that may be configured to execute one or more software modules. In addition to executing an operating system, the processor 21 may be configured to execute one or more software applications, including a web browser, a telephone application, an email program, or other software application.

The processor 21 can be configured to communicate with an array driver 22. The array driver 22 can include a row driver circuit 24 and a column driver circuit 26 that provide signals to, e.g., a display array or panel 30. The cross section of the IMOD display device illustrated in FIG. 1 is shown by the lines 1-1 in FIG. 2. Although FIG. 2 illustrates a 3×3 array of IMODs for the sake of clarity, the display array 30 may contain a very large number of IMODs, and may have a different number of IMODs in rows than in columns, and vice versa.

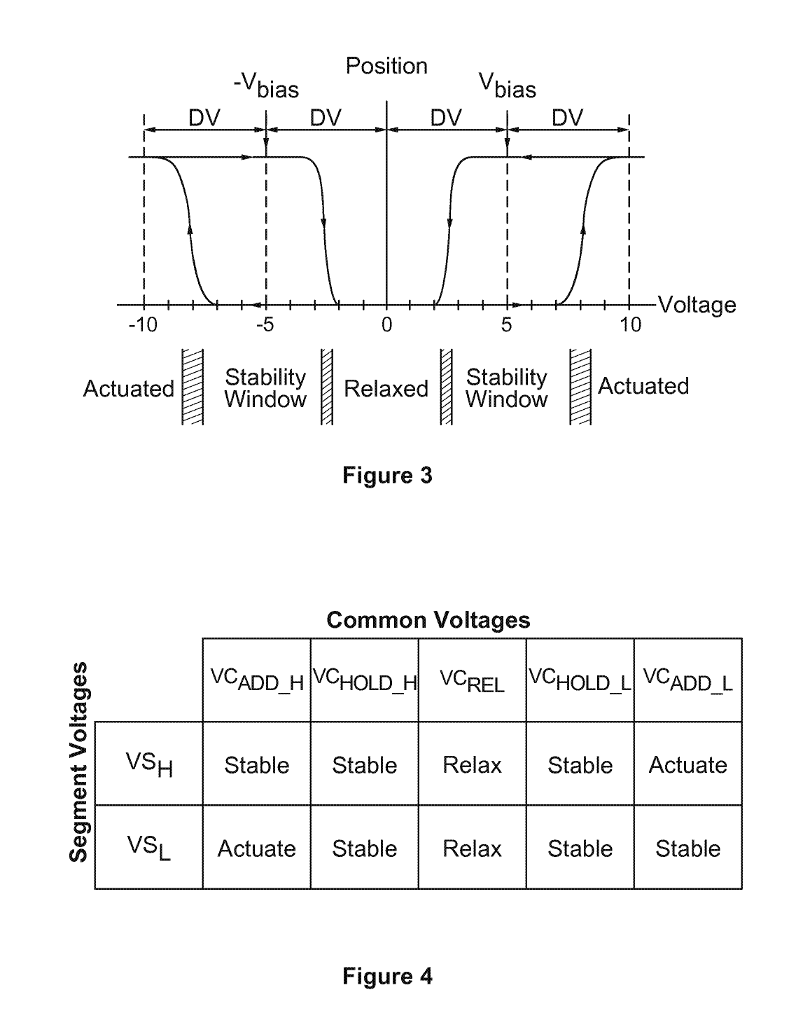

FIG. 3 shows an example of a diagram illustrating movable reflective layer position versus applied voltage for the interferometric modulator of FIG. 1. For MEMS interferometric modulators, the row/column (i.e., common/segment) write procedure may take advantage of a hysteresis property of these devices as illustrated in FIG. 3. An interferometric modulator may require, for example, about a 10-volt potential difference to cause the movable reflective layer, or mirror, to change from the relaxed state to the actuated state. When the voltage is reduced from that value, the movable reflective layer maintains its state as the voltage drops back below, e.g., 10 volts, however, the movable reflective layer does not relax completely until the voltage drops below 2 volts. Thus, a range of voltage, approximately 3 to 7 volts, as shown in FIG. 3, exists where there is a window of applied voltage within which the device is stable in either the relaxed or actuated state. This is referred to herein as the “hysteresis window” or “stability window.” For a display array 30 having the hysteresis characteristics of FIG. 3, the row/column write procedure can be designed to address one or more rows at a time, such that during the addressing of a given row, pixels in the addressed row that are to be actuated are exposed to a voltage difference of about 10 volts, and pixels that are to be relaxed are exposed to a voltage difference of near zero volts. After addressing, the pixels are exposed to a steady state or bias voltage difference of approximately 5-volts such that they remain in the previous strobing state. In this example, after being addressed, each pixel sees a potential difference within the “stability window” of about 3-7 volts. This hysteresis property feature enables the pixel design, e.g., illustrated in FIG. 1, to remain stable in either an actuated or relaxed pre-existing state under the same applied voltage conditions. Since each IMOD pixel, whether in the actuated or relaxed state, is essentially a capacitor formed by the fixed and moving reflective layers, this stable state can be held at a steady voltage within the hysteresis window without substantially consuming or losing power. Moreover, essentially little or no current flows into the IMOD pixel if the applied voltage potential remains substantially fixed.

In some implementations, a frame of an image may be created by applying data signals in the form of “segment” voltages along the set of column electrodes, in accordance with the desired change (if any) to the state of the pixels in a given row. Each row of the array can be addressed in turn, such that the frame is written one row at a time. To write the desired data to the pixels in a first row, segment voltages corresponding to the desired state of the pixels in the first row can be applied on the column electrodes, and a first row pulse in the form of a specific “common” voltage or signal can be applied to the first row electrode. The set of segment voltages can then be changed to correspond to the desired change (if any) to the state of the pixels in the second row, and a second common voltage can be applied to the second row electrode. In some implementations, the pixels in the first row are unaffected by the change in the segment voltages applied along the column electrodes, and remain in the state they were set to during the first common voltage row pulse. This process may be repeated for the entire series of rows, or alternatively, columns, in a sequential fashion to produce the image frame. The frames can be refreshed and/or updated with new image data by continually repeating this process at some desired number of frames per second.

The combination of segment and common signals applied across each pixel (that is, the potential difference across each pixel) determines the resulting state of each pixel. FIG. 4 shows an example of a table illustrating various states of an interferometric modulator when various common and segment voltages are applied. As will be readily understood by one having ordinary skill in the art, the “segment” voltages can be applied to either the column electrodes or the row electrodes, and the “common” voltages can be applied to the other of the column electrodes or the row electrodes.

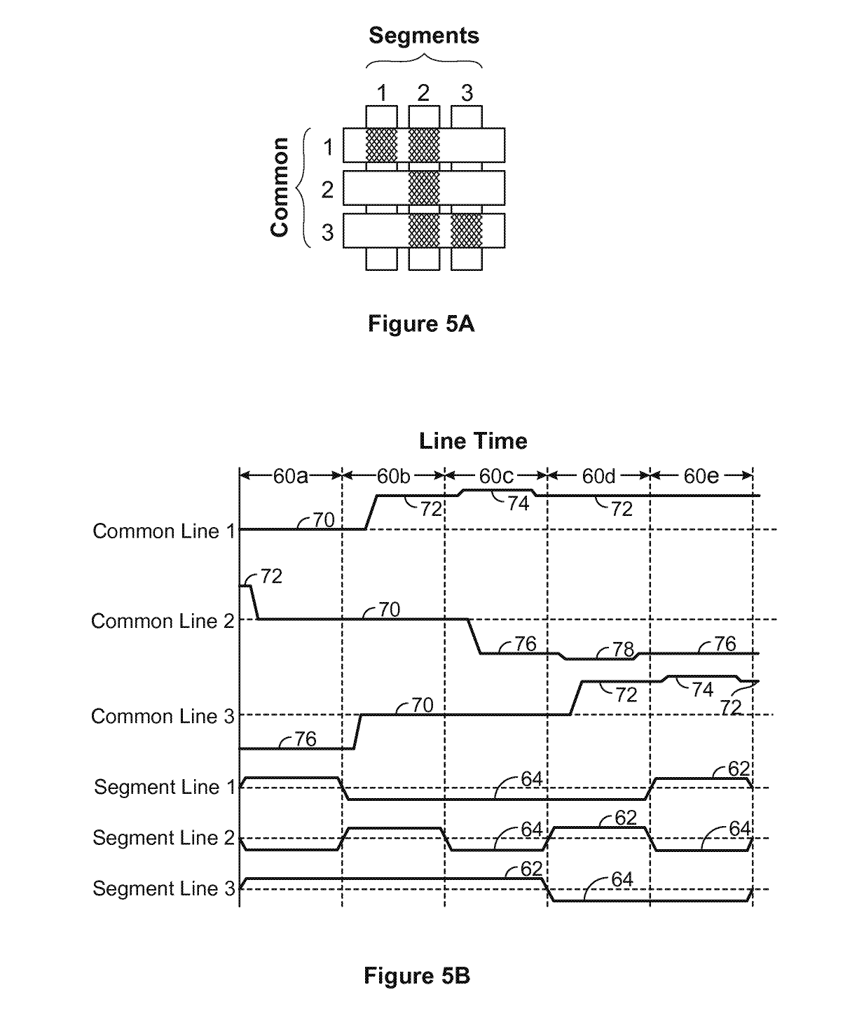

As illustrated in FIG. 4 (as well as in the timing diagram shown in FIG. 5B), when a release voltage VC_{REL} is applied along a common line, all interferometric modulator elements along the common line will be placed in a relaxed state, alternatively referred to as a released or unactuated state, regardless of the voltage applied along the segment lines, i.e., high segment voltage VS_{H} and low segment voltage VS_{L}. In particular, when the release voltage VC_{REL} is applied along a common line, the potential voltage across the modulator (alternatively referred to as a pixel voltage) is within the relaxation window (see FIG. 3, also referred to as a release window) both when the high segment voltage VS_{H} and the low segment voltage VS_{L} are applied along the corresponding segment line for that pixel.

When a hold voltage is applied on a common line, such as a high hold voltage VC_{HOLD}_{_{—}}_{H} or a low hold voltage VC_{HOLD}_{_{—}}_{L}, the state of the interferometric modulator will remain constant. For example, a relaxed IMOD will remain in a relaxed position, and an actuated IMOD will remain in an actuated position. The hold voltages can be selected such that the pixel voltage will remain within a stability window both when the high segment voltage VS_{H} and the low segment voltage VS_{L} are applied along the corresponding segment line. Thus, the segment voltage swing, i.e., the difference between the high VS_{H} and low segment voltage VS_{L}, is less than the width of either the positive or the negative stability window.

When an addressing, or actuation, voltage is applied on a common line, such as a high addressing voltage VC_{ADD}_{_{—}}_{H} or a low addressing voltage VC_{ADD}_{_{—}}_{L}, data can be selectively written to the modulators along that line by application of segment voltages along the respective segment lines. The segment voltages may be selected such that actuation is dependent upon the segment voltage applied. When an addressing voltage is applied along a common line, application of one segment voltage will result in a pixel voltage within a stability window, causing the pixel to remain unactuated. In contrast, application of the other segment voltage will result in a pixel voltage beyond the stability window, resulting in actuation of the pixel. The particular segment voltage which causes actuation can vary depending upon which addressing voltage is used. In some implementations, when the high addressing voltage VC_{ADD}_{_{—}}_{H} is applied along the common line, application of the high segment voltage VS_{H} can cause a modulator to remain in its current position, while application of the low segment voltage VS_{L} can cause actuation of the modulator. As a corollary, the effect of the segment voltages can be the opposite when a low addressing voltage VC_{ADD}_{_{—}}_{L} is applied, with high segment voltage VS_{H} causing actuation of the modulator, and low segment voltage VS_{L} having no effect (i.e., remaining stable) on the state of the modulator.

In some implementations, hold voltages, address voltages, and segment voltages may be used which always produce the same polarity potential difference across the modulators. In some other implementations, signals can be used which alternate the polarity of the potential difference of the modulators. Alternation of the polarity across the modulators (that is, alternation of the polarity of write procedures) may reduce or inhibit charge accumulation which could occur after repeated write operations of a single polarity.

FIG. 5A shows an example of a diagram illustrating a frame of display data in the 3×3 interferometric modulator display of FIG. 2. FIG. 5B shows an example of a timing diagram for common and segment signals that may be used to write the frame of display data illustrated in FIG. 5A. The signals can be applied to the, e.g., 3×3 array of FIG. 2, which will ultimately result in the line time 60e display arrangement illustrated in FIG. 5A. The actuated modulators in FIG. 5A are in a dark-state, i.e., where a substantial portion of the reflected light is outside of the visible spectrum so as to result in a dark appearance to, e.g., a viewer. Prior to writing the frame illustrated in FIG. 5A, the pixels can be in any state, but the write procedure illustrated in the timing diagram of FIG. 5B presumes that each modulator has been released and resides in an unactuated state before the first line time 60a.

During the first line time 60a, a release voltage 70 is applied on common line 1; the voltage applied on common line 2 begins at a high hold voltage 72 and moves to a release voltage 70; and a low hold voltage 76 is applied along common line 3. Thus, the modulators (common 1, segment 1), (1,2) and (1,3) along common line 1 remain in a relaxed, or unactuated, state for the duration of the first line time 60a, the modulators (2,1), (2,2) and (2,3) along common line 2 will move to a relaxed state, and the modulators (3,1), (3,2) and (3,3) along common line 3 will remain in their previous state. With reference to FIG. 4, the segment voltages applied along segment lines 1, 2 and 3 will have no effect on the state of the interferometric modulators, as none of common lines 1, 2 or 3 are being exposed to voltage levels causing actuation during line time 60a (i.e., VC_{REL}—relax and VC_{HOLD}_{_{—}}_{L}—stable).

During the second line time 60b, the voltage on common line 1 moves to a high hold voltage 72, and all modulators along common line 1 remain in a relaxed state regardless of the segment voltage applied because no addressing, or actuation, voltage was applied on the common line 1. The modulators along common line 2 remain in a relaxed state due to the application of the release voltage 70, and the modulators (3,1), (3,2) and (3,3) along common line 3 will relax when the voltage along common line 3 moves to a release voltage 70.

During the third line time 60c, common line 1 is addressed by applying a high address voltage 74 on common line 1. Because a low segment voltage 64 is applied along segment lines 1 and 2 during the application of this address voltage, the pixel voltage across modulators (1,1) and (1,2) is greater than the high end of the positive stability window (i.e., the voltage differential exceeded a predefined threshold) of the modulators, and the modulators (1,1) and (1,2) are actuated. Conversely, because a high segment voltage 62 is applied along segment line 3, the pixel voltage across modulator (1,3) is less than that of modulators (1,1) and (1,2), and remains within the positive stability window of the modulator; modulator (1,3) thus remains relaxed. Also during line time 60c, the voltage along common line 2 decreases to a low hold voltage 76, and the voltage along common line 3 remains at a release voltage 70, leaving the modulators along common lines 2 and 3 in a relaxed position.

During the fourth line time 60d, the voltage on common line 1 returns to a high hold voltage 72, leaving the modulators along common line 1 in their respective addressed states. The voltage on common line 2 is decreased to a low address voltage 78. Because a high segment voltage 62 is applied along segment line 2, the pixel voltage across modulator (2,2) is below the lower end of the negative stability window of the modulator, causing the modulator (2,2) to actuate. Conversely, because a low segment voltage 64 is applied along segment lines 1 and 3, the modulators (2,1) and (2,3) remain in a relaxed position. The voltage on common line 3 increases to a high hold voltage 72, leaving the modulators along common line 3 in a relaxed state.

Finally, during the fifth line time 60e, the voltage on common line 1 remains at high hold voltage 72, and the voltage on common line 2 remains at a low hold voltage 76, leaving the modulators along common lines 1 and 2 in their respective addressed states. The voltage on common line 3 increases to a high address voltage 74 to address the modulators along common line 3. As a low segment voltage 64 is applied on segment lines 2 and 3, the modulators (3,2) and (3,3) actuate, while the high segment voltage 62 applied along segment line 1 causes modulator (3,1) to remain in a relaxed position. Thus, at the end of the fifth line time 60e, the 3×3 pixel array is in the state shown in FIG. 5A, and will remain in that state as long as the hold voltages are applied along the common lines, regardless of variations in the segment voltage which may occur when modulators along other common lines (not shown) are being addressed.

In the timing diagram of FIG. 5B, a given write procedure (i.e., line times 60a-60e) can include the use of either high hold and address voltages, or low hold and address voltages. Once the write procedure has been completed for a given common line (and the common voltage is set to the hold voltage having the same polarity as the actuation voltage), the pixel voltage remains within a given stability window, and does not pass through the relaxation window until a release voltage is applied on that common line. Furthermore, as each modulator is released as part of the write procedure prior to addressing the modulator, the actuation time of a modulator, rather than the release time, may determine the necessary line time. Specifically, in implementations in which the release time of a modulator is greater than the actuation time, the release voltage may be applied for longer than a single line time, as depicted in FIG. 5B. In some other implementations, voltages applied along common lines or segment lines may vary to account for variations in the actuation and release voltages of different modulators, such as modulators of different colors.

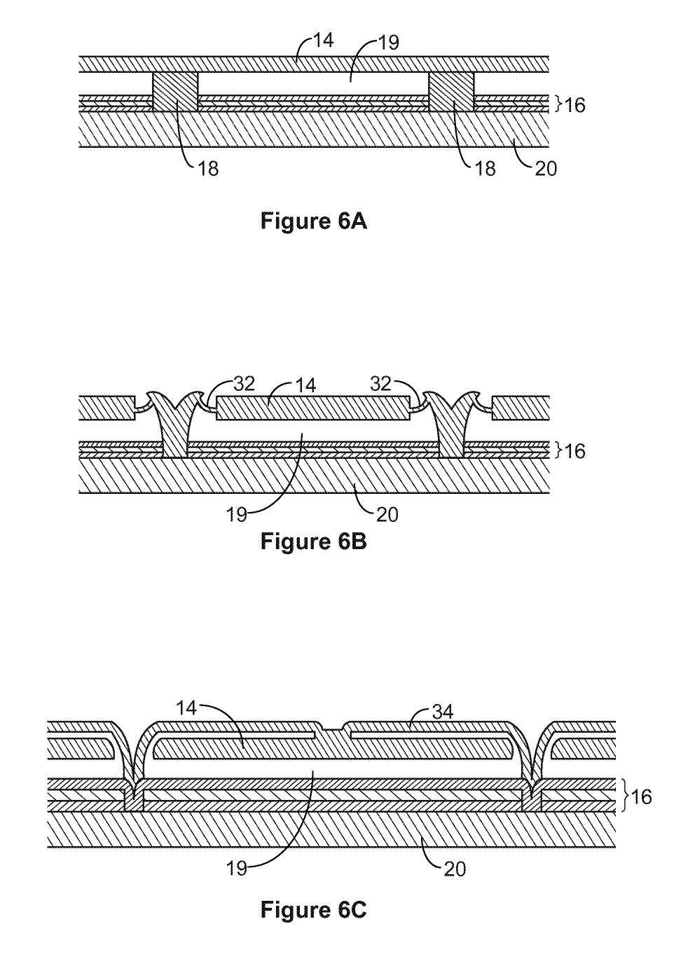

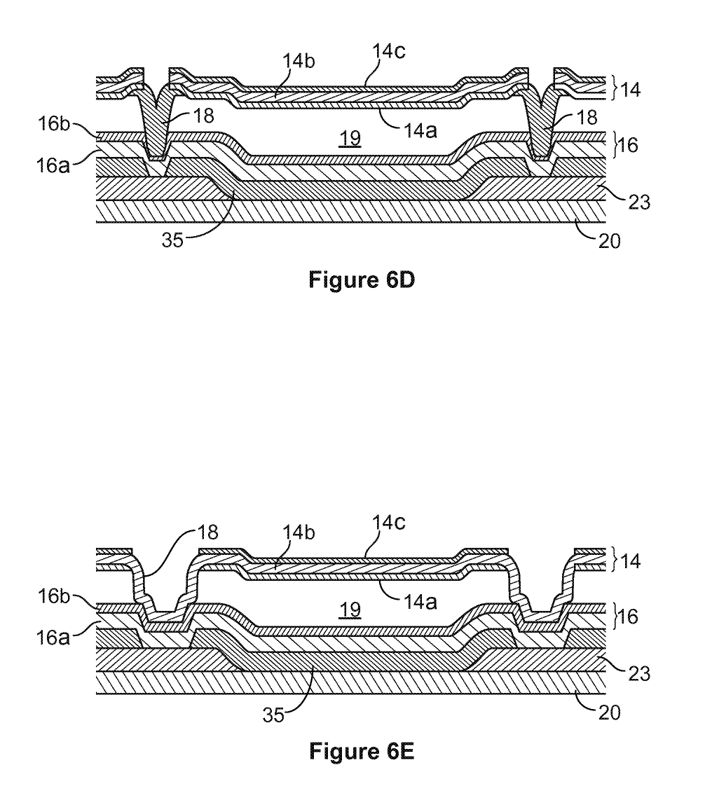

The details of the structure of interferometric modulators that operate in accordance with the principles set forth above may vary widely. For example, FIGS. 6A-6E show examples of cross-sections of varying implementations of interferometric modulators, including the movable reflective layer 14 and its supporting structures. FIG. 6A shows an example of a partial cross-section of the interferometric modulator display of FIG. 1, where a strip of metal material, i.e., the movable reflective layer 14 is deposited on supports 18 extending orthogonally from the substrate 20. In FIG. 6B, the movable reflective layer 14 of each IMOD is generally square or rectangular in shape and attached to supports at or near the corners, on tethers 32. In FIG. 6C, the movable reflective layer 14 is generally square or rectangular in shape and suspended from a deformable layer 34, which may include a flexible metal. The deformable layer 34 can connect, directly or indirectly, to the substrate 20 around the perimeter of the movable reflective layer 14. These connections are herein referred to as support posts. The implementation shown in FIG. 6C has additional benefits deriving from the decoupling of the optical functions of the movable reflective layer 14 from its mechanical functions, which are carried out by the deformable layer 34. This decoupling allows the structural design and materials used for the reflective layer 14 and those used for the deformable layer 34 to be optimized independently of one another.

FIG. 6D shows another example of an IMOD, where the movable reflective layer 14 includes a reflective sub-layer 14a. The movable reflective layer 14 rests on a support structure, such as support posts 18. The support posts 18 provide separation of the movable reflective layer 14 from the lower stationary electrode (i.e., part of the optical stack 16 in the illustrated IMOD) so that a gap 19 is formed between the movable reflective layer 14 and the optical stack 16, for example when the movable reflective layer 14 is in a relaxed position. The movable reflective layer 14 also can include a conductive layer 14c, which may be configured to serve as an electrode, and a support layer 14b. In this example, the conductive layer 14c is disposed on one side of the support layer 14b, distal from the substrate 20, and the reflective sub-layer 14a is disposed on the other side of the support layer 14b, proximal to the substrate 20. In some implementations, the reflective sub-layer 14a can be conductive and can be disposed between the support layer 14b and the optical stack 16. The support layer 14b can include one or more layers of a dielectric material, for example, silicon oxynitride (SiON) or silicon dioxide (SiO₂). In some implementations, the support layer 14b can be a stack of layers, such as, for example, an SiO₂/SiON/SiO₂ tri-layer stack. Either or both of the reflective sub-layer 14a and the conductive layer 14c can include, e.g., an aluminum (Al) alloy with about 0.5% copper (Cu), or another reflective metallic material. Employing conductive layers 14a, 14c above and below the dielectric support layer 14b can balance stresses and provide enhanced conduction. In some implementations, the reflective sub-layer 14a and the conductive layer 14c can be formed of different materials for a variety of design purposes, such as achieving specific stress profiles within the movable reflective layer 14.

As illustrated in FIG. 6D, some implementations also can include a black mask structure 23. The black mask structure 23 can be formed in optically inactive regions (e.g., between pixels or under posts 18) to absorb ambient or stray light. The black mask structure 23 also can improve the optical properties of a display device by inhibiting light from being reflected from or transmitted through inactive portions of the display, thereby increasing the contrast ratio. Additionally, the black mask structure 23 can be conductive and be configured to function as an electrical bussing layer. In some implementations, the row electrodes can be connected to the black mask structure 23 to reduce the resistance of the connected row electrode. The black mask structure 23 can be formed using a variety of methods, including deposition and patterning techniques. The black mask structure 23 can include one or more layers. For example, in some implementations, the black mask structure 23 includes a molybdenum-chromium (MoCr) layer that serves as an optical absorber, an SiO₂ layer, and an aluminum alloy that serves as a reflector and a bussing layer, with a thickness in the range of about 30-80 Å, 500-1000 Å, and 500-6000 Å, respectively. The one or more layers can be patterned using a variety of techniques, including photolithography and dry etching, including, for example, carbon tetrafluoromethane (CF₄) and/or oxygen (O₂) for the MoCr and SiO₂ layers and chlorine (Cl₂) and/or boron trichloride (BCl₃) for the aluminum alloy layer. In some implementations, the black mask 23 can be an etalon or interferometric stack structure. In such interferometric stack black mask structures 23, the conductive absorbers can be used to transmit or bus signals between lower, stationary electrodes in the optical stack 16 of each row or column. In some implementations, a spacer layer 35 can serve to generally electrically isolate the absorber layer 16a from the conductive layers in the black mask 23.

FIG. 6E shows another example of an IMOD, where the movable reflective layer 14 is self-supporting. In contrast with FIG. 6D, the implementation of FIG. 6E does not include support posts 18. Instead, the movable reflective layer 14 contacts the underlying optical stack 16 at multiple locations, and the curvature of the movable reflective layer 14 provides sufficient support that the movable reflective layer 14 returns to the unactuated position of FIG. 6E when the voltage across the interferometric modulator is insufficient to cause actuation. The optical stack 16, which may contain a plurality of several different layers, is shown here for clarity including an optical absorber 16a, and a dielectric 16b. In some implementations, the optical absorber 16a may serve both as a fixed electrode and as a partially reflective layer.

In implementations such as those shown in FIGS. 6A-6E, the IMODs function as direct-view devices, in which images are viewed from the front side of the transparent substrate 20, i.e., the side opposite to that upon which the modulator is arranged. In these implementations, the back portions of the device (that is, any portion of the display device behind the movable reflective layer 14, including, for example, the deformable layer 34 illustrated in FIG. 6C) can be configured and operated upon without impacting or negatively affecting the image quality of the display device, because the reflective layer 14 optically shields those portions of the device. For example, in some implementations a bus structure (not illustrated) can be included behind the movable reflective layer 14 which provides the ability to separate the optical properties of the modulator from the electromechanical properties of the modulator, such as voltage addressing and the movements that result from such addressing. Additionally, the implementations of FIGS. 6A-6E can simplify processing, such as, e.g., patterning.

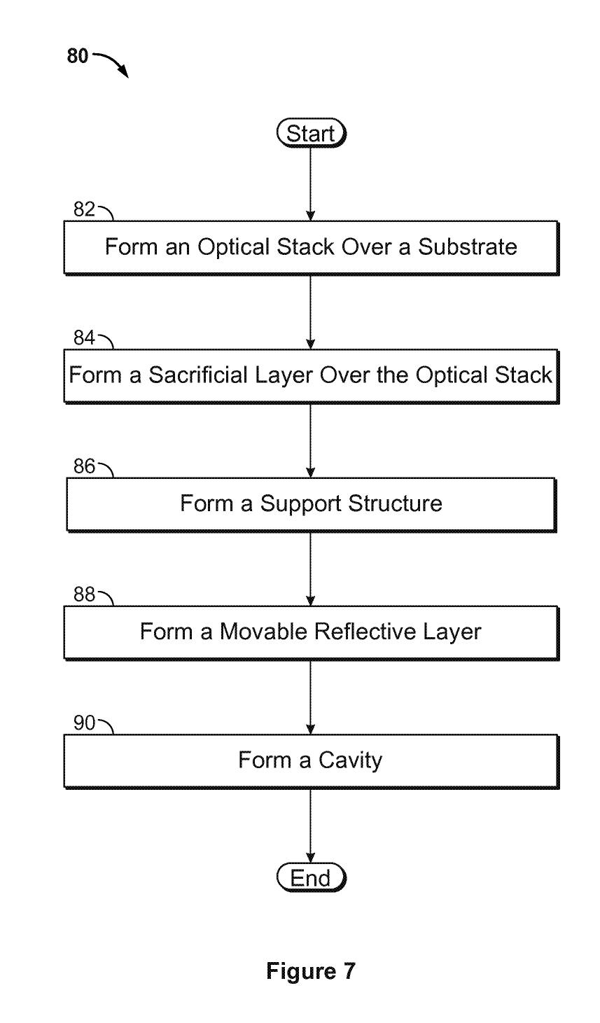

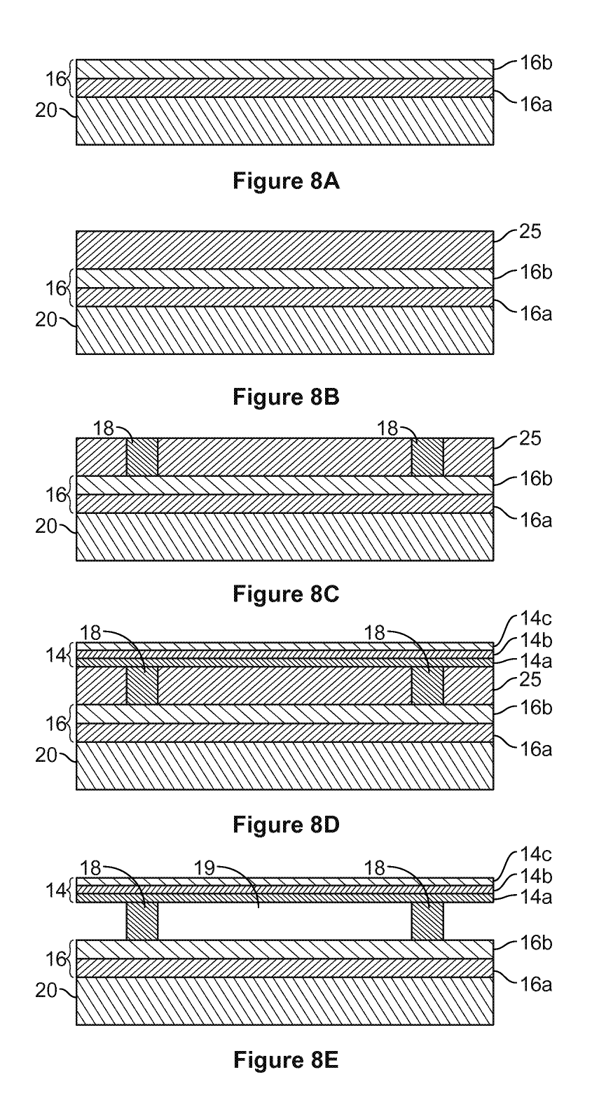

FIG. 7 shows an example of a flow diagram illustrating a manufacturing process 80 for an interferometric modulator, and FIGS. 8A-8E show examples of cross-sectional schematic illustrations of corresponding stages of such a manufacturing process 80. In some implementations, the manufacturing process 80 can be implemented to manufacture, e.g., interferometric modulators of the general type illustrated in FIGS. 1 and 6, in addition to other blocks not shown in FIG. 7. With reference to FIGS. 1, 6 and 7, the process 80 begins at block 82 with the formation of the optical stack 16 over the substrate 20. FIG. 8A illustrates such an optical stack 16 formed over the substrate 20. The substrate 20 may be a transparent substrate such as glass or plastic, it may be flexible or relatively stiff and unbending, and may have been subjected to prior preparation processes, e.g., cleaning, to facilitate efficient formation of the optical stack 16. As discussed above, the optical stack 16 can be electrically conductive, partially transparent and partially reflective and may be fabricated, for example, by depositing one or more layers having the desired properties onto the transparent substrate 20. In FIG. 8A, the optical stack 16 includes a multilayer structure having sub-layers 16a and 16b, although more or fewer sub-layers may be included in some other implementations. In some implementations, one of the sub-layers 16a, 16b can be configured with both optically absorptive and conductive properties, such as the combined conductor/absorber sub-layer 16a. Additionally, one or more of the sub-layers 16a, 16b can be patterned into parallel strips, and may form row electrodes in a display device. Such patterning can be performed by a masking and etching process or another suitable process known in the art. In some implementations, one of the sub-layers 16a, 16b can be an insulating or dielectric layer, such as sub-layer 16b that is deposited over one or more metal layers (e.g., one or more reflective and/or conductive layers). In addition, the optical stack 16 can be patterned into individual and parallel strips that form the rows of the display.

The process 80 continues at block 84 with the formation of a sacrificial layer 25 over the optical stack 16. The sacrificial layer 25 is later removed (e.g., at block 90) to form the cavity 19 and thus the sacrificial layer 25 is not shown in the resulting interferometric modulators 12 illustrated in FIG. 1. FIG. 8B illustrates a partially fabricated device including a sacrificial layer 25 formed over the optical stack 16. The formation of the sacrificial layer 25 over the optical stack 16 may include deposition of a xenon difluoride (XeF₂)-etchable material such as molybdenum (Mo) or amorphous silicon (Si), in a thickness selected to provide, after subsequent removal, a gap or cavity 19 (see also FIGS. 1 and 8E) having a desired design size. Deposition of the sacrificial material may be carried out using deposition techniques such as physical vapor deposition (PVD, e.g., sputtering), plasma-enhanced chemical vapor deposition (PECVD), thermal chemical vapor deposition (thermal CVD), or spin-coating.

The process 80 continues at block 86 with the formation of a support structure e.g., a post 18 as illustrated in FIGS. 1, 6 and 8C. The formation of the post 18 may include patterning the sacrificial layer 25 to form a support structure aperture, then depositing a material (e.g., a polymer or an inorganic material, e.g., silicon oxide) into the aperture to form the post 18, using a deposition method such as PVD, PECVD, thermal CVD, or spin-coating. In some implementations, the support structure aperture formed in the sacrificial layer can extend through both the sacrificial layer 25 and the optical stack 16 to the underlying substrate 20, so that the lower end of the post 18 contacts the substrate 20 as illustrated in FIG. 6A. Alternatively, as depicted in FIG. 8C, the aperture formed in the sacrificial layer 25 can extend through the sacrificial layer 25, but not through the optical stack 16. For example, FIG. 8E illustrates the lower ends of the support posts 18 in contact with an upper surface of the optical stack 16. The post 18, or other support structures, may be formed by depositing a layer of support structure material over the sacrificial layer 25 and patterning to remove portions of the support structure material located away from apertures in the sacrificial layer 25. The support structures may be located within the apertures, as illustrated in FIG. 8C, but also can, at least partially, extend over a portion of the sacrificial layer 25. As noted above, the patterning of the sacrificial layer 25 and/or the support posts 18 can be performed by a patterning and etching process, but also may be performed by alternative etching methods.

The process 80 continues at block 88 with the formation of a movable reflective layer or membrane such as the movable reflective layer 14 illustrated in FIGS. 1, 6 and 8D. The movable reflective layer 14 may be formed by employing one or more deposition processes, e.g., reflective layer (e.g., aluminum, aluminum alloy) deposition, along with one or more patterning, masking, and/or etching processes. The movable reflective layer 14 can be electrically conductive, and referred to as an electrically conductive layer. In some implementations, the movable reflective layer 14 may include a plurality of sub-layers 14a, 14b, 14c as shown in FIG. 8D. In some implementations, one or more of the sub-layers, such as sub-layers 14a, 14c, may include highly reflective sub-layers selected for their optical properties, and another sub-layer 14b may include a mechanical sub-layer selected for its mechanical properties. Since the sacrificial layer 25 is still present in the partially fabricated interferometric modulator formed at block 88, the movable reflective layer 14 is typically not movable at this stage. A partially fabricated IMOD that contains a sacrificial layer 25 also may be referred to herein as an “unreleased” IMOD. As described above in connection with FIG. 1, the movable reflective layer 14 can be patterned into individual and parallel strips that form the columns of the display.

The process 80 continues at block 90 with the formation of a cavity, e.g., cavity 19 as illustrated in FIGS. 1, 6 and 8E. The cavity 19 may be formed by exposing the sacrificial material 25 (deposited at block 84) to an etchant. For example, an etchable sacrificial material such as Mo or amorphous Si may be removed by dry chemical etching, e.g., by exposing the sacrificial layer 25 to a gaseous or vaporous etchant, such as vapors derived from solid XeF₂ for a period of time that is effective to remove the desired amount of material, typically selectively removed relative to the structures surrounding the cavity 19. Other combinations of etchable sacrificial material and etching methods, e.g. wet etching and/or plasma etching, also may be used. Since the sacrificial layer 25 is removed during block 90, the movable reflective layer 14 is typically movable after this stage. After removal of the sacrificial material 25, the resulting fully or partially fabricated IMOD may be referred to herein as a “released” IMOD.

EMS devices also may be incorporated in various different electronic circuits. One type of EMS device is an EMS variable capacitance device or an EMS varactor. In some EMS varactors, an electrode that serves as a movable layer may receive a DC voltage and a RF signal. From a device and circuit perspective, however, it may be desirable to have separate bias electrodes and RF electrodes in an EMS varactor. Separate bias electrodes and RF electrodes for a movable layer of an EMS varactor may be incorporated in a member that includes a dielectric beam.

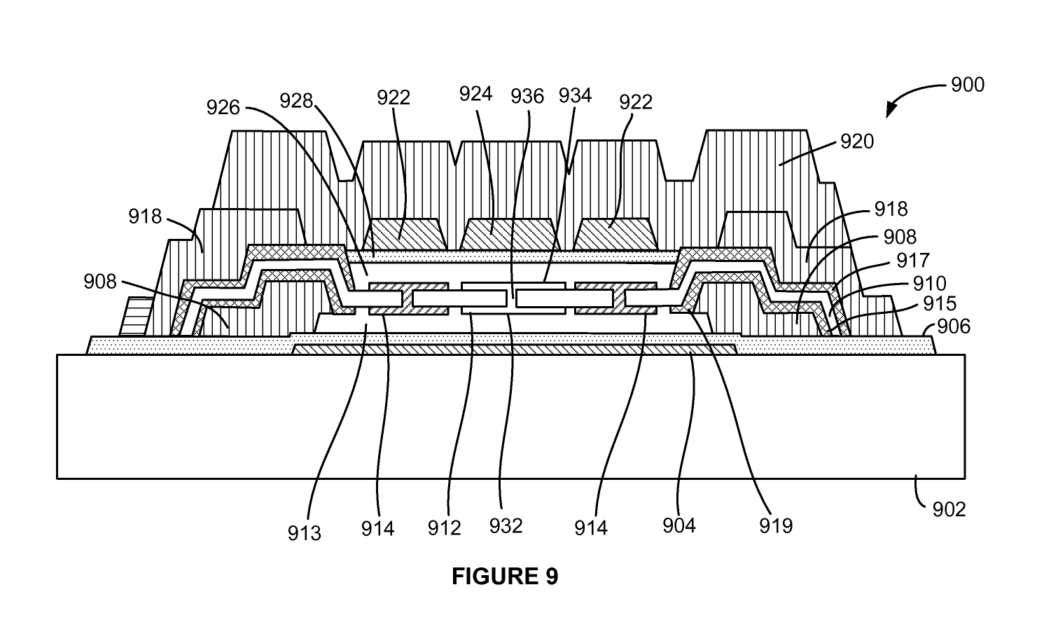

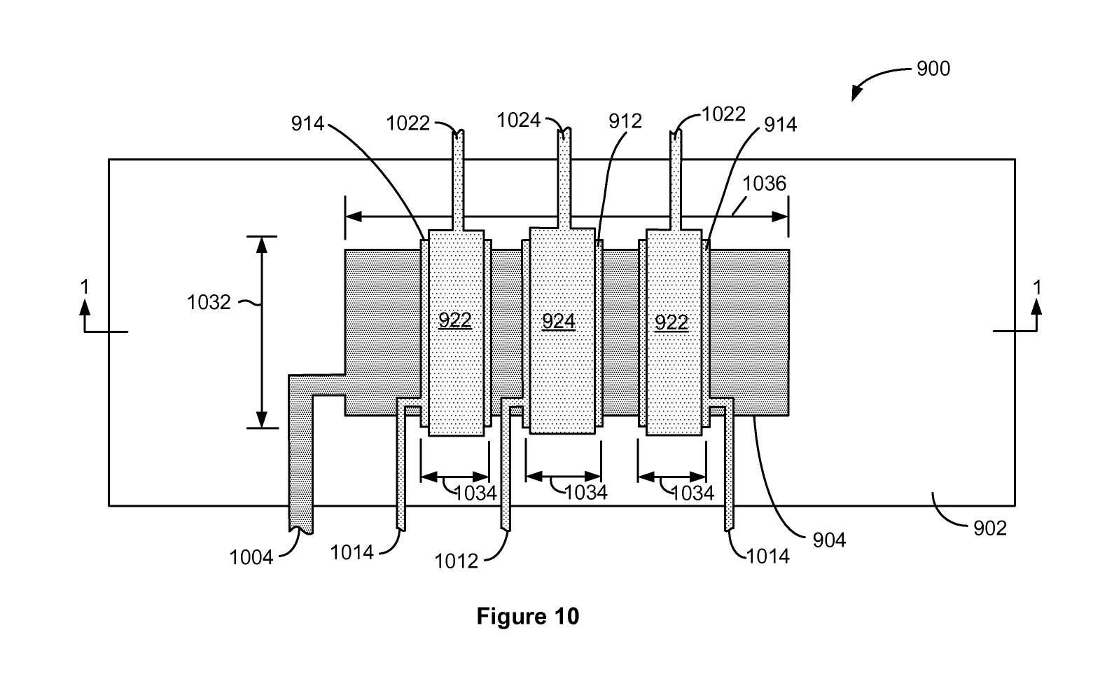

FIGS. 9 and 10 show examples of schematic illustrations of an EMS varactor. FIG. 9 shows an example of a cross-sectional schematic illustration of an EMS varactor. FIG. 10 shows an example of a top-down schematic illustration of the EMS varactor shown in FIG. 9. The cross-sectional schematic illustration of the EMS varactor shown in FIG. 9 is shown by the lines 1-1 in FIG. 10. The dimensions given below for the components of the EMS varactor are examples of dimensions for a specific EMS varactor. The dimensions may be scaled up or down, depending on intended application of the EMS varactor. For example, a higher voltage EMS varactor may use thicker layers of material.

As shown in FIG. 9, the EMS varactor 900 includes a substrate 902 having a first bias electrode 904 on the substrate 902. A non-planarized first dielectric layer 906 is on the substrate 902 and on the first bias electrode 904. First dielectric supports 908 on the non-planarized first dielectric layer 906 support a member 919 including a second dielectric layer (also referred to as a dielectric beam) 910, a first RF electrode 912, and ground electrodes 914. In some implementations, the first RF electrode 912 and the ground electrodes 914 may be electrically isolated from each other. The member 919 and the non-planarized first dielectric layer 906 define a first air gap 913. In some implementations, the first air gap 913 may be about 100 nanometers (nm) to 300 nm thick, or about 200 nm thick. Portions of the member 919 not overlying the first air gap 913 include a first metal layer 915 and a second metal layer 917, with the second dielectric layer 910 between the two metal layers. Second dielectric supports 918 on the member 919 support a non-planarized third dielectric layer 920. The non-planarized third dielectric layer 920 is over a metal layer including second bias electrodes 922 and a second RF electrode 924. A fourth dielectric layer 928 may serve to insulate the second bias electrodes 922 and the second RF electrode 924. The member 919 and the fourth dielectric layer 928 define a second air gap 926. In some implementations, the second air gap 926 may be about 100 nm to 300 nm thick, or about 200 nm thick.

The member 919 may include a plane of symmetry substantially parallel to a plane containing the first bias electrode 904 for the portion of the member 919 overlying the first air gap 913. For example, the member 919 shown in FIG. 9 includes a plane of symmetry. A plane of symmetry of the member 919 also may be substantially parallel to a plane containing the second bias electrodes 922 and the second RF electrode 924.

The substrate 902 may include different substrate materials, including transparent materials, non-transparent materials, flexible materials, rigid materials, or combinations of these. In some implementations, the substrate may be a semiconductor (for example, Si or indium phosphide (InP)), silicon-on-insulator (SOI), a glass (such as a display glass or a borosilicate glass), a flexible plastic, or a metal foil. In some implementations, the substrate 902 can vary in size from a few microns to hundreds of millimeters.

The first bias electrode 904, the ground electrodes 914, the first RF electrode 912, the second bias electrodes 922, and the second RF electrode 924 may be any number of different metals, including aluminum (Al), copper (Cu), molybdenum (Mo), tantalum (Ta), chromium (Cr), neodymium (Nd), tungsten (W), titanium (Ti), and an alloy including at least one of these metals. For example, in some implementations, the electrodes may be Al or Al doped with silicon (Si) or Cu. In some implementations, all of the electrodes may be made of the same metal. For example, in some implementations, the second bias electrodes 922 and the second RF electrode 924 may be made of the same metal. In some other implementations, the second bias electrodes 922 and the second RF electrode 924 may be different metals. In some implementations, for example, the second bias electrodes 922 may be a metal with a higher resistivity than the metal of the second RF electrode 924. The second bias electrodes 922 being a metal with a higher resistivity than the metal of the second RF electrode 924 may reduce RF power loss, in some implementations. The first bias electrode 904 may be about 0.5 microns to 1 micron thick. The second bias electrodes 922 and the second RF electrode 924 may be about 1 micron to 3 microns thick.

Each of the ground electrodes 914 and the first RF electrode 912 includes a first metal layer 932, a second metal layer 934, and a metal 936 coupling the two metal layers. For clarity, the first metal layer 932, the second metal layer 934, and the metal 936 are indicated only for the first RF electrode 912 in FIG. 9. The first metal layer 932 of each electrode 912 and 914 may be exposed to the first air gap 913, and the second metal layer 934 of each electrode 912 and 914 may be exposed to the second air gap 926. In some implementations, the first metal layer 932 and the second metal layer 934 of each electrode 912 and 914 may be about 250 nm to 750 nm thick or about 500 nm thick. In some implementations, the metal 936 of each electrode 912 and 914 may be about 500 nm to 1 micron thick or about 500 nm thick. Thus, each electrode 912 and 914 may have a thickness of about 1 micron to 2.5 microns, or about 1.5 microns, in some implementations.

The dielectric material of the non-planarized first dielectric layer 906, the first dielectric supports 908, the second dielectric layer 910, the second dielectric supports 918, the non-planarized third dielectric layer 920, and the fourth dielectric layer 928 may include a number of different dielectric materials. In some implementations, the dielectric materials may include silicon dioxide (SiO₂), aluminum oxide (Al₂O₃), hafnium oxide (HfO₂), titanium oxide (TiO₂), silicon oxynitride (SiON), or silicon nitride (SiN).

In some implementations, the non-planarized first dielectric layer 906 may be a SiO₂ layer. The non-planarized first dielectric layer 906 may have a thickness of less than about 200 nm for low voltage (e.g., less than about 4 volts) implementations of the EMS varactor 900. For high voltage (e.g., about 20 volts to 100 volts) implementations of the EMS varactor 900, the non-planarized first dielectric layer 906 may be thicker than about 200 nm. The second dielectric layer 910 of the member 919 will generally be thicker than each of the first metal layer 932 and the second metal layer 934 and be the same thickness as the metal 936, i.e., about 500 nm to 1 micron thick or about 500 nm thick, in some implementations. In some implementations, the fourth dielectric layer 928 may have a thickness of about 10 nm to 30 nm.

In some implementations, the first dielectric supports 908 and the second dielectric supports 918 may be SiO₂ or SiON. In some implementations, the dielectric supports may not form a planar layer of material. A dielectric support may have a thickness of about 0.5 microns to 2 microns in different regions of the dielectric support.

In some implementations, the non-planarized third dielectric layer 920 may be about 3 microns to 7 microns thick or about 5 microns thick. In some implementations, the non-planarized third dielectric layer 920 may be thick enough such that it does not mechanically move into the second air gap 926 during operation of the EMS varactor 900. In some implementations, the non-planarized third dielectric layer 920 may include a number of different dielectric layers (e.g., five to six) stacked on one another. In some implementations, the non-planarized third dielectric layer 920 may form an encapsulation shell for the EMS varactor 900. An encapsulation shell may protect the EMS varactor 900 from the atmosphere or the environment.

In the top-down view of the EMS varactor 900 shown in FIG. 10, the substrate 902 and the electrodes of the EMS varactor 900 are shown. The dielectric layers and the dielectric supports are not shown for clarity. As shown in FIG. 10, terminal 1004 is a lead to the first bias electrode 904, terminal 1012 is a lead to the to the first RF electrode 912, terminals 1014 are leads to the ground electrodes 914, terminals 1022 are leads to the second bias electrodes 922, and terminal 1024 is a lead to the second RF electrode 924. Thus, the EMS varactor 900 is a three-layer, five-terminal varactor.

The configuration of the terminals shown in FIG. 10 is an example of one configuration of the terminals, and other terminal configurations are possible. For example, the terminals may connect to different sides or regions of the electrodes. Further, while the first bias electrode 904, the first RF electrode 912, the ground electrodes 914, the second bias electrodes 922, and the second RF electrode 924 are shown as having a rectangular shape in FIG. 10, other electrode shapes are possible. For example, the electrodes may have a circular shape or a square shape.

In some implementations, a dimension 1032 of the electrodes 904, 912, 914, 922, and 924 may be about 20 microns to 80 microns. In some implementations, a dimension 1034 of a ground electrode 914, the first RF electrode 912, a second bias electrode 922, and the second RF electrode 924 may be about 20 microns to 40 microns, or about 30 microns. While the dimension 1034 of a ground electrode 914, the first RF electrode 912, a second bias electrode 922, and the second RF electrode 924 are shown as being the same in FIG. 10, the dimension 1034 of each of a ground electrode 914, the first RF electrode 912, a second bias electrode 922, and the second RF electrode 924 may be different, in some implementations. A dimension 1036 of the first RF electrode 904 may be about 100 microns to 200 microns, or about 150 microns. The dimensions 1032, 1034, and 1036 are example dimensions of one implementation of an EMS varactor. As noted above, the dimensions may be scaled up or down, depending on the expected operation conditions of the EMS varactor.

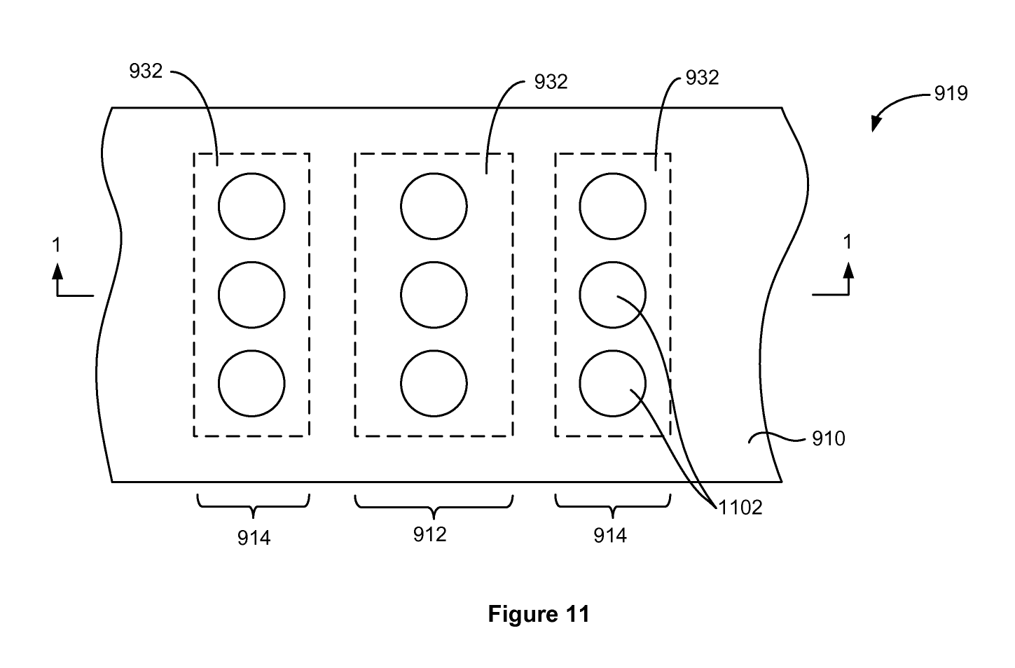

FIG. 11 shows an example of a top-down schematic illustration of a portion of the member of the EMS varactor shown in FIGS. 9 and 10. The portion of the member 919 of the EMS varactor 900 shown in FIG. 11 includes the first metal layer 932 of the ground electrodes 914 and the first RF electrode 912. Overlying the first metal layer 932 of the ground electrodes 914 and the first RF electrode 912 is the second dielectric layer 910. The second dielectric layer 910 includes a number of vias 1102 through the second dielectric layer 910. The vias 1102 in the second dielectric layer 910 may be filled with the metal 936, which may couple or electrically connect the first metal layer 932 to the second metal layer 934 of each of the ground electrodes 914 and the first RF electrode 912.

In operation, the ground electrodes 914 of the EMS varactor 900 may be at a ground potential. A first DC voltage may be applied to the first bias electrode 904, which may cause the member 919 to mechanically move into the first air gap 913 due to the ground electrodes 914 being attracted to the first bias electrode 904. For example, when the potential difference between the ground electrodes 914 and the first bias electrode 904 is large, the member 919 may be drawn into contact with the non-planarized first dielectric layer 906. When the potential difference between the ground electrodes 914 and the first bias electrode 904 is smaller, the member 919 may be drawn into the first air gap 913 but not into contact with the non-planarized first dielectric layer 906. A second DC voltage may be applied to the second bias electrodes 922, which may cause the member 919 to mechanically move into the second air gap 926 due to the ground electrodes 914 being attracted to the second bias electrodes 922. For example, when the potential difference between the ground electrodes 914 and the second bias electrodes 922 is large, the member 919 may be drawn into contact with the fourth dielectric layer 928. When the potential difference between the ground electrodes 914 and the second bias electrodes 922 is smaller, the member 919 may be drawn into the second air gap 926 but not into contact with the fourth dielectric layer 928. Thus, the member 919 may be flexible, in some implementations.

Thus, DC voltages applied to the first bias electrode 904 and to the second bias electrodes 922 may cause the distance between the first RF electrode 912 and the second RF electrode 924 to vary. By varying the distance between the first RF electrode 912 and the second RF electrode 924, a capacitance between the first RF electrode 912 and the second RF electrode 924 may be varied. For example, the second RF electrode 924 may receive an input signal, and the variation of the distance between the first RF electrode 912 and the second RF electrode 924 may vary the capacitance observed by the input signal. Alternatively, the first RF electrode 912 may receive an input signal, and the variation of the distance between the first RF electrode 912 and the second RF electrode 924 may vary the capacitance observed by the input signal. In some implementations of the varactor 900, high tuning capacitance ratios may be attained. High tuning capacitance ratios may be attained due to the ground electrodes 914 allowing the first RF electrode 912 to have a greater degree of movement (e.g., to move closer to or further away from the second RF electrode 924) when the EMS varactor 900 is in operation.

In some other implementations of the EMS varactor 900, the portions of the member 919 overlying the first dielectric supports 908 may include the second dielectric layer 910 without the first metal layer 915 and the second metal layer 917. Not including the first metal layer 915 and the second metal layer 917 in these portions of the member 919 may reduce parasitic capacitance and increase the tuning capacitance ratio. The first metal layer 915 and the second metal layer 917 being included in these portions of the member 919 may aid in the fabrication of the EMS varactor 900, however.

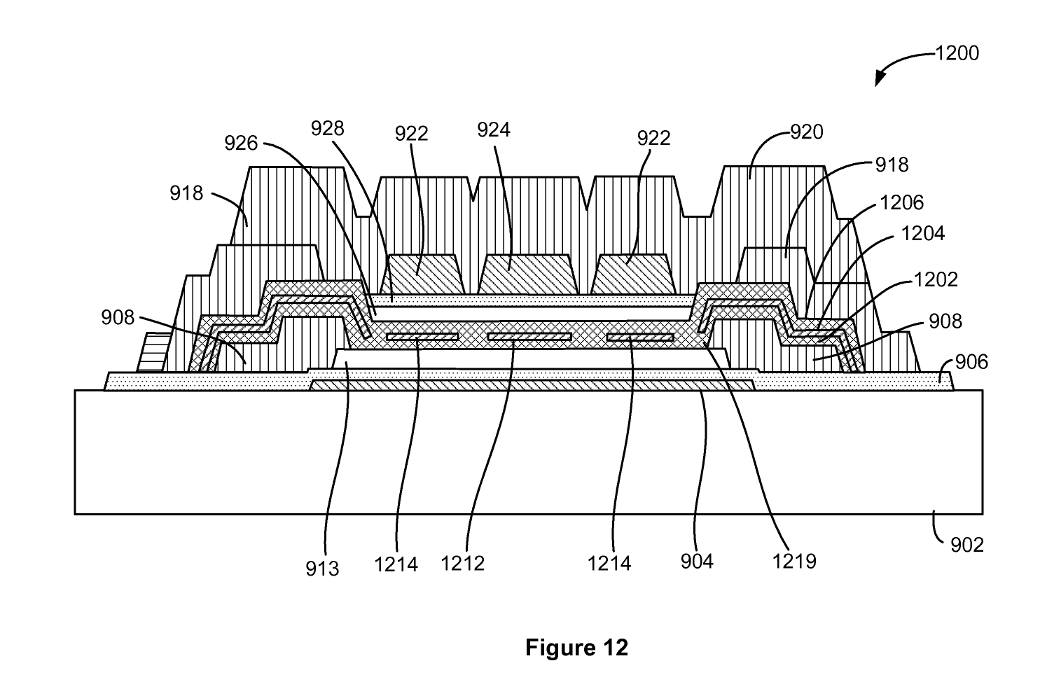

FIG. 12 shows an example of a cross-sectional schematic illustration of an EMS varactor. The EMS varactor shown in FIG. 12 includes a different member structure than the EMS varactor shown in FIGS. 9 and 10.

As shown in FIG. 12, the EMS varactor 1200 includes a substrate 902. A first bias electrode 904 resides on the substrate 902. A non-planarized first dielectric layer 906 is on the substrate 902 and on the first bias electrode 904. First dielectric supports 908 on the non-planarized first dielectric layer 906 support a member 1219. The member 1219 may include dielectric layers 1202 and 1206, a metal layer 1204, a first RF electrode 1212, and two ground electrodes 1214. In some implementations, the first RF electrode 1212 and the ground electrodes 1214 may be electrically isolated from each other. The structure formed by the dielectric layers 1202 and 1206 is also referred to as a dielectric beam. The member 1219 and the non-planarized first dielectric layer 906 define a first air gap 913. In some implementations, the first air gap 913 may be about 100 nm to 300 nm thick, or about 200 nm thick. Second dielectric supports 918 on the member 1219 support a non-planarized third dielectric layer 920. The non-planarized third dielectric layer 920 is over a metal layer including second bias electrodes 922 and a second RF electrode 924. A fourth dielectric layer 928 may serve to insulate the second bias electrodes 922 and the second RF electrode 924. The member 1219 and fourth dielectric layer 928 define a second air gap 926. In some implementations, the second air gap 926 may be about 100 nm to 300 nm thick, or about 200 nm thick. A number of the components of the EMS varactor 1200, which are also included in the EMS varactor 900, have been described in more detail with reference to FIG. 9 above.

The member 1219 may include a plane of symmetry substantially parallel a plane containing the first bias electrode 904 for the portion of the member 1219 overlying the first air gap 913. For example, the member 1219 shown in FIG. 12 includes a plane of symmetry. A plane of symmetry of the member 1219 also may be substantially parallel to a plane containing the second bias electrodes 922 and the second RF electrode 924.

The ground electrodes 1214, the first RF electrode 1212, and the metal layer 1204 may be any number of different metals, including Al, Cu, Mo, Ta, Cr, Nd, W, Ti, and an alloy including at least one of these metals. For example, in some implementations, the electrodes may be Al or Al doped with silicon (Si) or Cu. In some implementations, all of the electrodes may be made of the same metal. In some implementations, the ground electrodes 1214, the first RF electrode 1212, and the metal layer 1204 may be about 250 nm to 750 nm thick, or about 500 nm thick.

The dielectric material of the dielectric layers 1202 and 1206 of the member 1219 may include SiO₂, Al₂O₃, HfO₂, TiO₂, SiON, or SiN. In some implementations, the dielectric layers 1202 and 1206 may each be about 250 nm to 750 nm thick, or about 500 nm thick. Thus, with the ground electrodes 1214, the first RF electrode 1212, and the metal layer 1204 each having a thickness of about 250 nm to 750 nm, the member 1219 may have a thickness of about 0.7 microns to 2.3 microns, or about 1.5 microns, in some implementations

In the EMS varactor 1200, the ground electrodes 1214 and the first RF electrode 1212 may be embedded in the dielectric layers 1202 and 1206. That is, surfaces of the ground electrodes 1214 and the first RF electrode 1212 may not be exposed to the first air gap 913 or the second air gap 926.

The EMS varactor 1200 may operate in a similar manner to the EMS varactor 900 shown in FIGS. 9 and 10. That is, a DC voltage may be applied to the first bias electrode 904 or to the second bias electrodes 922, which may cause the member 1219 to move into the first air gap 913 or into the second air gap 926. Thus, the member 1219 may be flexible, in some implementations. Thus, the member 1219 may also be referred to as a membrane in some implementations. The movement of the member 1219 may vary the distance between the first RF electrode 1212 and the second RF electrode 924. By varying the distance between the first RF electrode 1212 and the second RF electrode 924, a capacitance between the first RF electrode 1212 and the second RF electrode 924 may be varied.

In the operation of the EMS varactor 1200, because the ground electrodes 1214 and the first RF electrode 1212 may be embedded in the dielectric layers 1202 and 1206, the surfaces of these electrodes may not come into and out of contact with dielectric layers 906 or 928. Thus, the metals of the ground electrodes 1214 and the first RF electrode 1212 may not abrade or wear due to contact with the dielectric layers 906 or 928. This may increase the reliability of the EMS varactor 1200.

In some other implementations of the EMS varactor 1200, the portions of the member 1219 overlying the first dielectric supports 908 may include the dielectric layers 1202 and 1206 without the metal layer 1204. Not including the metal layer 1204 in these portions of the member 1219 may reduce parasitic capacitance and increase the tuning capacitance ratio. The metal layer 1204 being included in these portions of the member 1219 may aid in the fabrication of the EMS varactor 1200, however.

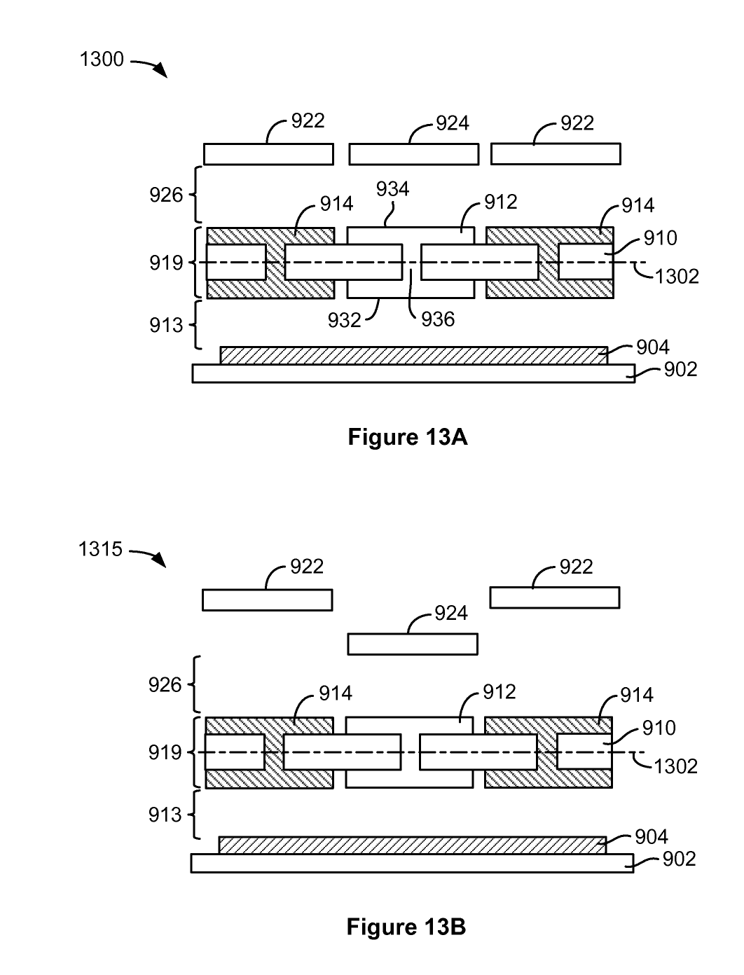

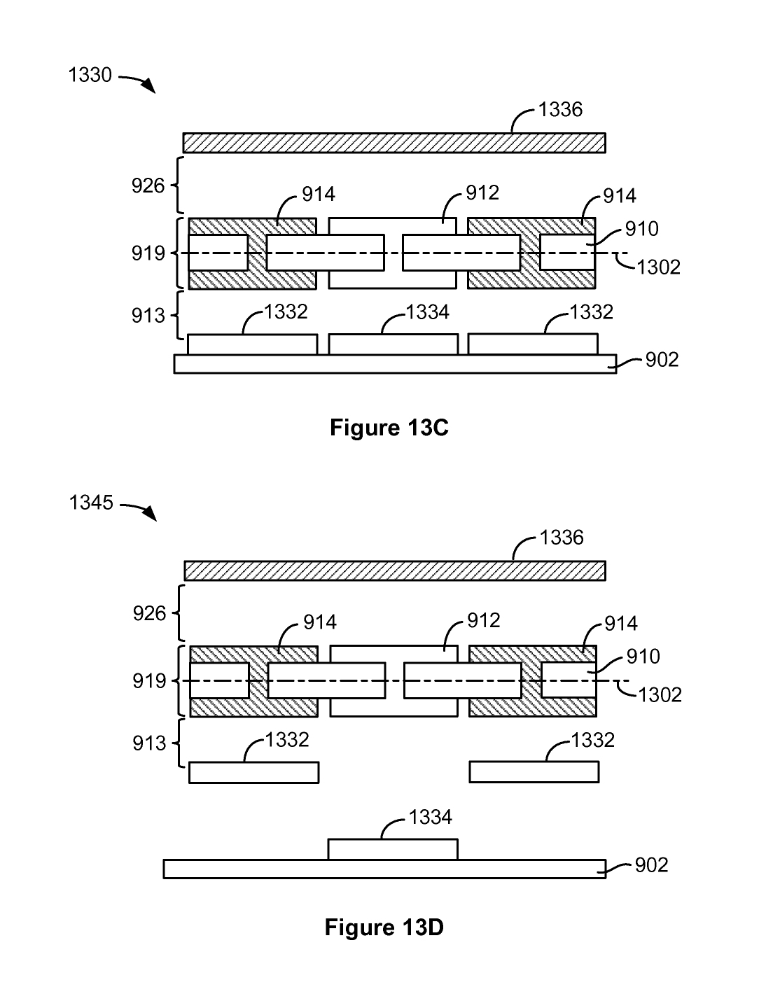

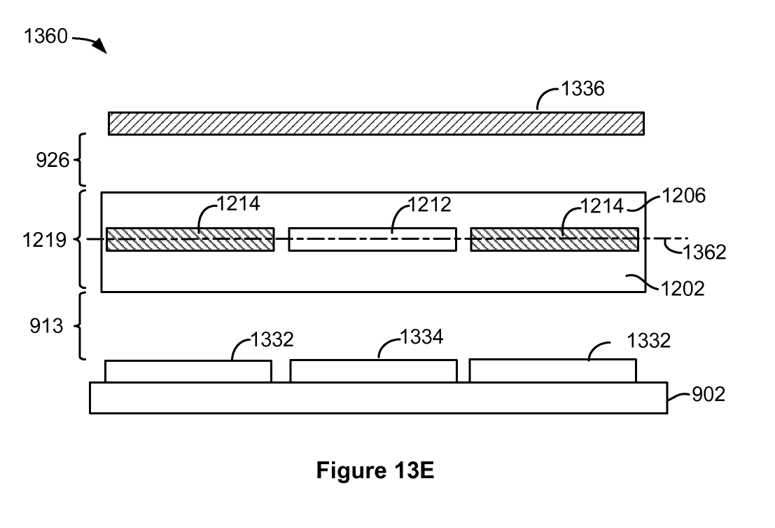

FIGS. 13A-13E show examples of cross-sectional schematic illustrations of EMS varactors. The cross-sectional schematic illustrations shown in FIGS. 13A-13E include simplified illustrations of the three-layer, five-terminal varactors disclosed herein. Not shown in FIGS. 13A-13E are the dielectric supports or the dielectric layers of the EMS varactors. The EMS varactors shown in FIGS. 13A-13E include different configurations of the bias electrodes and RF electrodes, as described below.

Implementations of the EMS varactor 1300 shown in FIG. 13A may be similar to the EMS varactor 900 shown in FIGS. 9 and 10. The EMS varactor 1300 includes a substrate 902 having a first bias electrode 904 on the substrate 902. A member 919 and the first bias electrode 904 may define a first air gap 913. The member 919 and a metal layer including second bias electrodes 922 and a second RF electrode 924 may define a second air gap 926. The second bias electrodes 922 and the second RF electrode 924 may be coplanar. Two objects are coplanar if they both lie in the same plane.

The member 919 may include a second dielectric layer (also referred to as a dielectric beam) 910, a first RF electrode 912, and ground electrodes 914. Each of the ground electrodes 914 and the first RF electrode 912 may include a first metal layer 932, a second metal layer 934, and a metal 936 coupling the two metal layers. For clarity, the first metal layer 932, the second metal layer 934, and the metal 936 are indicated only for the first RF electrode 912 in FIG. 13A. The first metal layer 932 of each electrode 912 and 914 may be exposed to the first air gap 913, and the second metal layer 934 of each electrode 912 and 914 may be exposed to the second air gap 926. In some implementations, the first RF electrode 912 and the ground electrodes 914 may be electrically isolated from each other. The member 919 may include a plane of symmetry substantially parallel to a plane containing the first bias electrode 904. For example, the member 919 shown in FIG. 13A includes a plane of symmetry, indicated by dashed line 1302. A plane of symmetry of the member 919 also may be substantially parallel to a plane containing the second bias electrodes 922 and the second RF electrode 924. The member 919 being symmetrical may improve the mechanical properties of the member 919, including the fatigue properties and the thermal stability, for example.

Implementations of the EMS varactor 1315 shown in FIG. 13B may be similar to the EMS varactor 900 shown in FIGS. 9 and 10. In the EMS varactor 1315 compared to the EMS varactor 1300 shown in FIG. 13A, the second bias electrodes 922 may be located at a location further from a member 919 than a second RF electrode 924. That is, the second bias electrodes 922 and the second RF electrode 924 may be non-coplanar, with the second RF electrode 924 being closer to the member 919 than the second bias electrodes 922.

As shown in FIG. 13B, the EMS varactor 1315 includes a substrate 902 having a first bias electrode 904 on the substrate 902. A member 919 and the first bias electrode 904 may define a first air gap 913. The member 919 and a metal layer including second bias electrodes 922 and a second RF electrode 924 may define a second air gap 926. The member 919 may include a second dielectric layer 910, a first RF electrode 912, and ground electrodes 914. In some implementations, the first RF electrode 912 and the ground electrodes 914 may be electrically isolated from each other. The member 919 may include a plane of symmetry substantially parallel a plane containing the first bias electrode 904. For example, the member 919 shown in FIG. 13B includes a plane of symmetry, indicated by the dashed line 1302. A plane of symmetry of the member 919 also may be substantially parallel to a plane containing the second bias electrodes 922 or a plane containing the second RF electrode 924.

In the EMS varactor 1315, having the second bias electrodes 922 located at a location further from a member 919 than a second RF electrode 924 may allow for a larger range of capacitances of the EMS varactor 1315. The second bias electrodes 922 may be located in a different plane than the second RF electrode 924, for example, by forming the second RF electrode 924, depositing a dielectric layer, and then forming the second bias electrodes 922.

Implementations of the EMS varactor 1330 shown in FIG. 13C may be similar to the EMS varactor 900 shown in FIGS. 9 and 10. In the EMS varactor 1330, however, second bias electrodes and a second RF electrode are on the substrate. As shown in FIG. 13C, the EMS varactor 1330 includes a substrate 902 having a metal layer including second bias electrodes 1332 and a second RF electrode 1334 on the substrate 902. The second bias electrodes 1332 and the second RF electrode 1334 may be coplanar, i.e., they both lie in the same plane. A member 919 and the metal layer including the second bias electrodes 1332 and the second RF electrode 1334 may define a first air gap 913. A first bias electrode 1336 and the member 919 may define a second air gap 926. The member 919 may include a second dielectric layer 910, a first RF electrode 912, and ground electrodes 914. In some implementations, the first RF electrode 912 and the ground electrodes 914 may be electrically isolated from each other. The member 919 may include a plane of symmetry substantially parallel a plane containing the first bias electrode 1336. For example, the member 919 shown in FIG. 13C includes a plane of symmetry, indicated by the dashed line 1302. A plane of symmetry of the member 919 also may be substantially parallel to a plane containing the second bias electrodes 922 and the second RF electrode 924.

In the EMS varactor 1330, during the fabrication process, a metal layer may be deposited on the substrate 902. The second bias electrodes 1332 and the second RF electrode 1334 may be formed from the metal layer. For example, various patterning techniques, including masking and/or etching techniques, may be used to form the second bias electrodes 1332 and the second RF electrode 1334 from the metal layer. The second bias electrodes 1332 and the second RF electrode 1334 may not form a flat surface, however. That is, the surface formed by the second bias electrodes 1332 and the second RF electrode 1334 may include features such as trenches and ridges, for example. A dielectric layer or layers may be deposited on the second bias electrodes 1332 and the second RF electrode 1334 and planarized to create a flat, planar surface on which the remainder of the EMS varactor 1330 may be fabricated.

Implementations of the EMS varactor 1345 shown in FIG. 13D may be similar to the EMS varactor 900 shown in FIGS. 9 and 10. In the EMS varactor 1345 compared to the EMS varactor 1330 shown in FIG. 13C, the second bias electrodes 1332 may be located at a location closer to a member 919 than the second RF electrode 1334. That is, the second bias electrodes 1332 and the second RF electrode 1334 may be non-coplanar, with the second RF electrode 1334 being further away from the member 919 than the second bias electrodes 1332.

As shown in FIG. 13D, the EMS varactor 1345 includes a substrate 902 having a metal layer including the second RF electrode 1334 on the substrate 902. The second bias electrodes 1332 may be associated with the substrate. For example, second bias electrode 1332 may be on a dielectric layer (not shown) that is on the substrate 902. A member 919 and the metal layer including the second bias electrodes 1332 and the second RF electrode 1334 may define a first air gap 913. A first bias electrode 1336 and the member 919 may define a second air gap 926. The member 919 may include a second dielectric layer 910, a first RF electrode 912, and ground electrodes 914. In some implementations, the first RF electrode 912 and the ground electrodes 914 may be electrically isolated from each other. The member 919 may include a plane of symmetry substantially parallel a plane containing the first bias electrode 1336. For example, the member 919 shown in FIG. 13D includes a plane of symmetry, indicated by dashed line 1302. A plane of symmetry of the member 919 also may be substantially parallel to a plane containing the second bias electrodes 1332 or a plane containing the second RF electrode 1334. In the EMS varactor 1345, having the second RF electrode 1334 located further away from the member 919 than the second bias electrodes 1332 may allow for higher RF power handling than the EMS varactor 1330 in FIG. 13C due to the large spacing between the second RF electrode 1334 and the first RF electrode 912.

During a fabrication process for the EMS varactor 1345, the second RF electrode 1334 may be formed on the substrate 902. Dielectric layers then may be deposited, followed by forming the second bias electrodes 1332. Planarization processes may be performed after forming the second RF electrode 1334 and/or after forming the second bias electrodes 1332. For example, after the second bias electrodes 1332 are formed, a dielectric layer may deposited on the second bias electrodes 1332 and exposed dielectric and then planarized to create a flat, planar surface on which the remainder of the EMS varactor 1345 may be fabricated.

Implementations of the EMS varactor 1360 shown in FIG. 13E may be similar to the EMS varactor 1200 shown in FIG. 12. In the EMS varactor 1360, however, second bias electrodes and a second RF electrode are on the substrate. As shown in FIG. 13E, the EMS varactor 1360 includes a substrate 902 having a metal layer residing thereon. The metal layer includes second bias electrodes 1332 and a second RF electrode 1334. A member 1219 and the metal layer including the second bias electrodes 1332 and the second RF electrode 1334 may define a first air gap 913. A first bias electrode 1336 and the member 1219 may define a second air gap 926. The member 1219 may include dielectric layers 1202 and 1206, a first RF electrode 1212, and ground electrodes 1214. In some implementations, the first RF electrode 1212 and the ground electrodes 1214 may be electrically isolated from each other. The structure formed by the dielectric layers 1202 and 1206 is also referred to as a dielectric beam. The member 1219 may include a plane of symmetry substantially parallel a plane containing the first bias electrode 1336. For example, the member 1219 shown in FIG. 13E includes a plane of symmetry, indicated by dashed line 1362. A plane of symmetry of the member 1219 also may be substantially parallel to a plane containing the second bias electrodes 1332 and the second RF electrode 1334. The member 1219 being symmetrical may improve the mechanical properties of the member 1219, including the fatigue properties and the thermal stability, for example. The ground electrodes 1214 and the first RF electrode 1212 may be embedded in the dielectric layers 1202 and 1206. That is, surfaces of the ground electrodes 1214 and the first RF electrode 1212 may not be exposed to the first air gap 913 or the second air gap 926.

Further details regarding the components of the EMS varactors shown in FIGS. 13A-13E are described above with respect to the EMS varactor 900 shown in FIGS. 9 and 10 and the EMS varactor 1200 shown in FIG. 12.

The EMS varactors described herein are examples of EMS varactors that may be formed having a member including a bias electrode and a RF electrode. Other designs of EMS varactors having a member including a bias electrode and a RF electrode are possible, however. For example, the member 919 or 1219 may be implemented with any of the bias electrode configurations disclosed herein. That is, the member 919 or 1219 may be implemented with the first bias electrode on the substrate as shown in FIGS. 9, 12, 13A, and 13B. The member 919 or 1219 also may be implemented with the second bias electrode on or associated with the substrate and the second RF electrode on the substrate as shown in FIGS. 13C-13E.

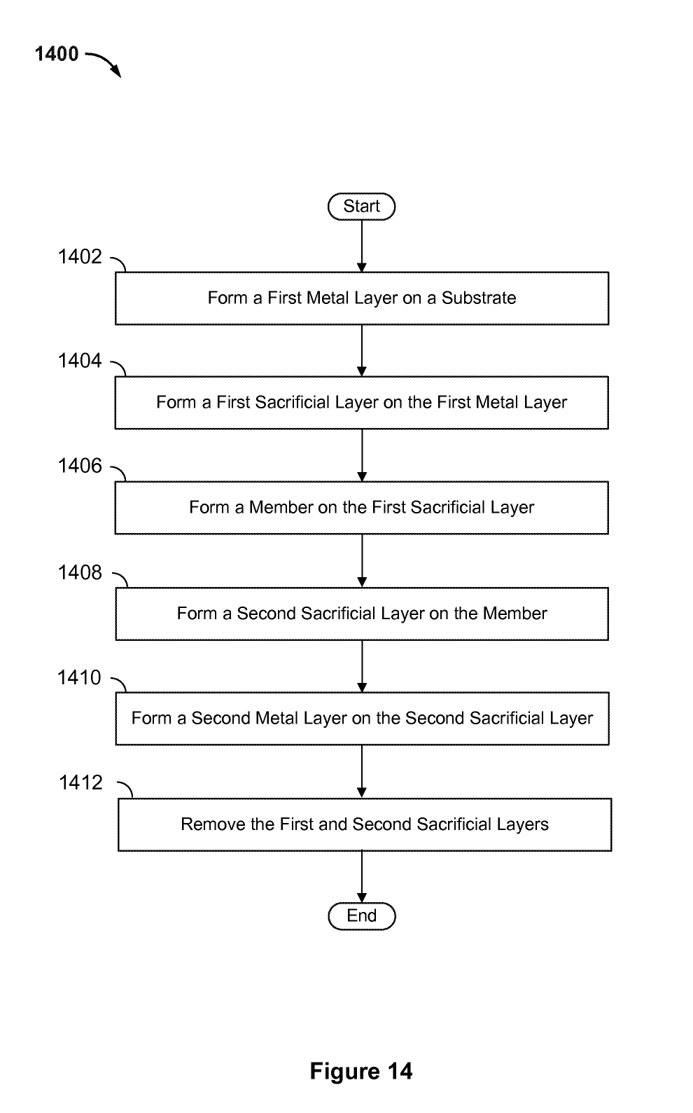

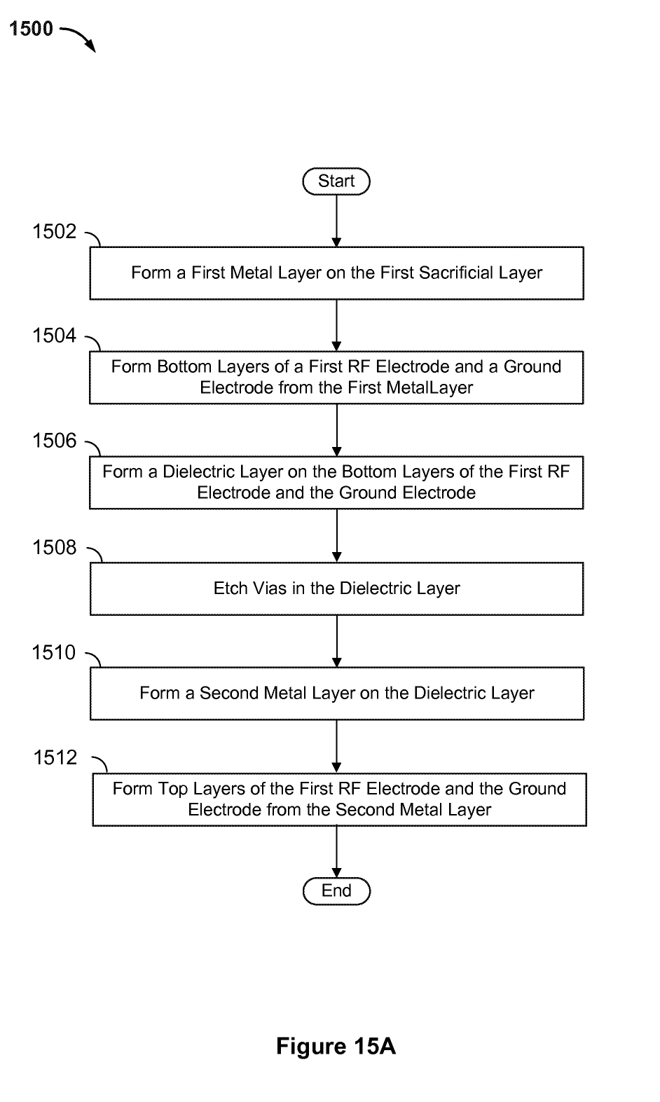

FIG. 14 shows an example of a flow diagram illustrating a manufacturing process for an EMS varactor. The operations of the process 1400 may be combined and/or rearranged to form any of the EMS varactors disclosed herein. In the process 1400, patterning techniques, including masking as well as etching processes, may be used to define the shapes of the different components of an EMS varactor during the manufacturing process.

Starting at block 1402 of the process 1400, a first metal layer is formed on a substrate. The substrate may include different substrate materials, including transparent materials, non-transparent materials, flexible materials, rigid materials, or combinations of these. The first metal layer may include Al, Cu, Mo, Ta, Cr, Nd, W, Ti, or an alloy including at least one of these metals. The first metal layer may be formed using deposition processes including PVD processes, CVD processes, and atomic layer deposition (ALD) processes.

In some implementations, the first metal layer may serve as a bias electrode. When the first metal layer is to serve as a bias electrode, a non-planarized dielectric layer may be deposited on the first metal layer. The non-planarized dielectric layer may include SiO₂, Al₂O₃, HfO₂, TiO₂, SiON, or SiN. The non-planarized dielectric layer may be formed using deposition processes including PVD processes, CVD processes including PECVD processes, and ALD processes.

In some other implementations, the first metal layer may serve as both a bias electrode and a RF electrode. When the first metal layer is to serve as both a bias electrode and a RF electrode, the bias electrode and the RF electrode may be formed from the first metal layer. For example, patterning techniques may be used to form the bias electrode and the RF electrode from the first metal layer such that the bias electrode and the radio frequency electrode formed are electrically isolated. After the patterning operations, however, the electrodes may not form a flat surface. That is, the surface formed by the electrodes may include features such as trenches and ridges, for example. A dielectric layer or layers may be deposited on the electrodes and planarized to create a flat, planar surface on which the remainder of the EMS varactor may be fabricated. The dielectric layers may include SiO₂, Al₂O₃, HfO₂, TiO₂, SiON, or SiN. The dielectric layers may be formed using deposition processes including PVD processes, CVD processes including PECVD processes, and ALD processes.

Returning to the process 1400, at block 1404 a first sacrificial layer is formed on the first metal layer. The first sacrificial layer may include a XeF₂-etchable material such as Mo or amorphous Si in a thickness and size selected to provide, after subsequent removal, a first air gap having a desired thickness and size. Some examples of the thickness of the first air gap have been discussed above. The first sacrificial layer may be formed using deposition processes including PVD processes and CVD processes, including PECVD processes.

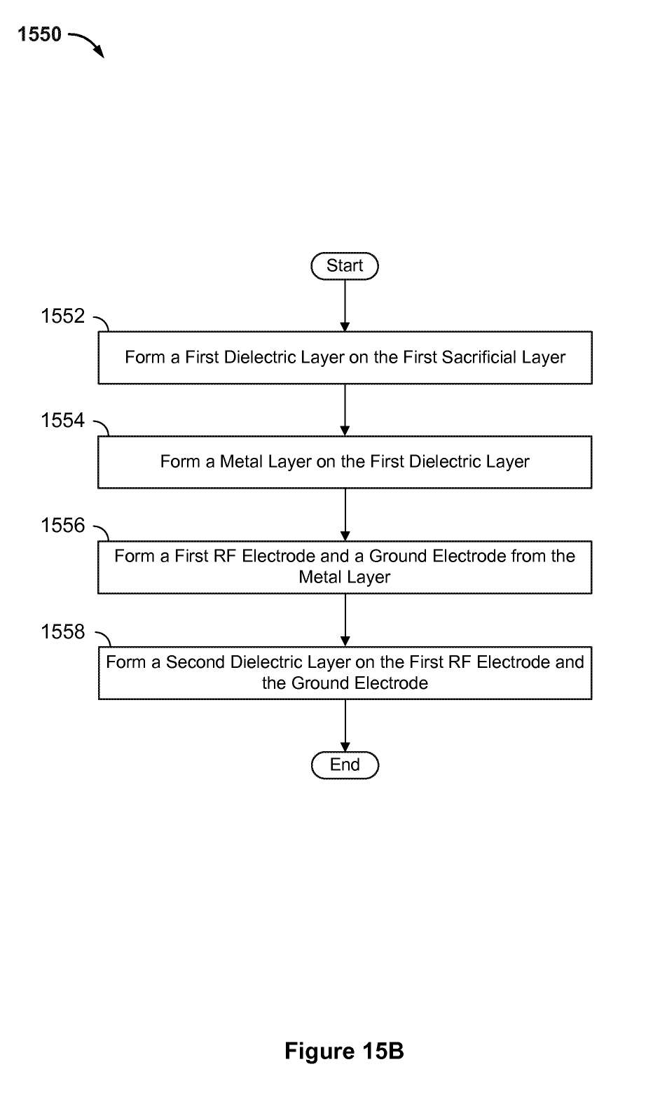

At block 1406, a member is formed on the sacrificial layer. The member may include a dielectric beam, a first radio frequency electrode, and a ground electrode. The member may be similar to the member 919 shown in FIG. 9 or the member 1219 shown in FIG. 12, for example. FIGS. 15A and 15B show examples of flow diagrams illustrating manufacturing processes for a member of an EMS varactor.

FIG. 15A shows an example of a flow diagram illustrating a manufacturing process for a member similar to the member 919. The metal layers of the member may be made of the same metals, in some implementations. For example, the metal layers may include Al, Cu, Mo, Ta, Cr, Nd, W, Ti, or an alloy including at least one of these metals. The metal layers may be formed using deposition processes including PVD processes, CVD processes, and ALD processes. The dielectric layer of the member may include SiO₂, Al₂O₃, HfO₂, TiO₂, SiON, or SiN. The dielectric layer may be formed using deposition processes including PVD processes, CVD processes including PECVD processes, and ALD processes.

Starting with block 1502 of the process 1500, a first metal layer is formed on the first sacrificial layer. At block 1504, a bottom layer of a first RF electrode and a bottom layer of a ground electrode are formed from the first metal layer. For example, patterning techniques may be used to form the bottom layer of the first RF electrode and the bottom layer of the ground electrode from the first metal layer. At block 1506, a dielectric layer is formed on the bottom layers of the first RF electrode and the ground electrode. At block 1508, vias are etched in the dielectric layer. The vias may be filled with a metal to electrically couple the bottom layers of the first RF electrode and the ground electrode to the top layers.

At block 1510, a second metal layer is formed on the dielectric layer. While forming the second metal layer, the vias etched in the dielectric layer at block 1508 may be filled with the metal of the second metal layer. At block 1512, a top layer of the first RF electrode and a top layer of the ground electrode are formed from the second metal layer. For example, patterning techniques may be used to form the top layer of the first RF electrode and the top layer of the ground electrode from the second metal layer. The metal filling the vias may serve to couple the bottom layer to the top layer of the first RF electrode and the bottom layer to the top layer of the ground electrode; that is, the metal filling the vias may serve to electrically connect the bottom layer to the top layer of the first RF electrode and the bottom layer to the top layer of the ground electrode.

FIG. 15B shows an example of a flow diagram illustrating a manufacturing process for a member similar to the member 1219. The metal layer of the member may include Al, Cu, Mo, Ta, Cr, Nd, W, Ti, or an alloy including at least one of these metals. The metal layers may be formed using deposition processes including PVD processes, CVD processes, and ALD processes. The dielectric layer of the member may include SiO₂, Al₂O₃, HfO₂, TiO₂, SiON, or SiN. The dielectric layer may be formed using deposition processes including PVD processes, CVD processes including PECVD processes, and ALD processes.

Starting with block 1552 of the process 1550, a first dielectric layer is formed on the first sacrificial layer. At block 1554, a metal layer is formed on the first dielectric layer. At block 1556, the first RF electrode and the ground electrode are formed from the metal layer. For example, patterning techniques may be used to form the first RF electrode and the ground electrode from the metal layer. At block 1558, a second dielectric layer is formed on the first RF electrode and the ground electrode. The first dielectric layer formed at block 1552 and the second dielectric layer formed at block 1558 may form the dielectric beam, and the first radio frequency electrode and the ground electrode formed in block 1556 are embedded in the dielectric beam.

Returning to the process 1400, at block 1408, a second sacrificial layer is formed on the member. The second sacrificial layer may include a XeF₂-etchable material such as Mo or amorphous Si in a thickness and size selected to provide, after subsequent removal, a second air gap having a desired thickness and size. Some examples of the thickness of the second air gap have been discussed above. The second sacrificial layer may be formed using deposition processes including PVD processes and CVD processes, including PECVD processes. In some implementations, the first sacrificial layer and the second sacrificial layer may include the same material.

At block 1410, a second metal layer is formed on the second sacrificial layer. The second metal layer may include Al, Cu, Mo, Ta, Cr, Nd, W, Ti, or an alloy including at least one of these metals. The second metal layer may be formed using deposition processes including PVD processes, CVD processes, and ALD processes.

In some implementations, the second metal layer may serve as a bias electrode. In some other implementations, the second metal layer may serve as both a bias electrode and a RF electrode. When the second metal layer is to serve as both a bias electrode and a RF electrode, each of the electrodes may be formed from the second metal layer. For example, patterning techniques may be used to form the bias electrode and the RF electrode from the second metal layer.

At block 1412, the first and the second sacrificial layers are removed. In some implementations, the sacrificial layers are Mo or amorphous Si, and XeF₂ may be used to remove the sacrificial layers.

In some implementations, a non-planarized dielectric layer may be formed on the second metal layer. The non-planarized dielectric layer may include SiO₂, Al₂O₃, HfO₂, TiO₂, SiON, SiN, or layers of these dielectrics. The non-planarized dielectric layer may be formed using deposition processes including PVD processes and CVD processes including PECVD processes.

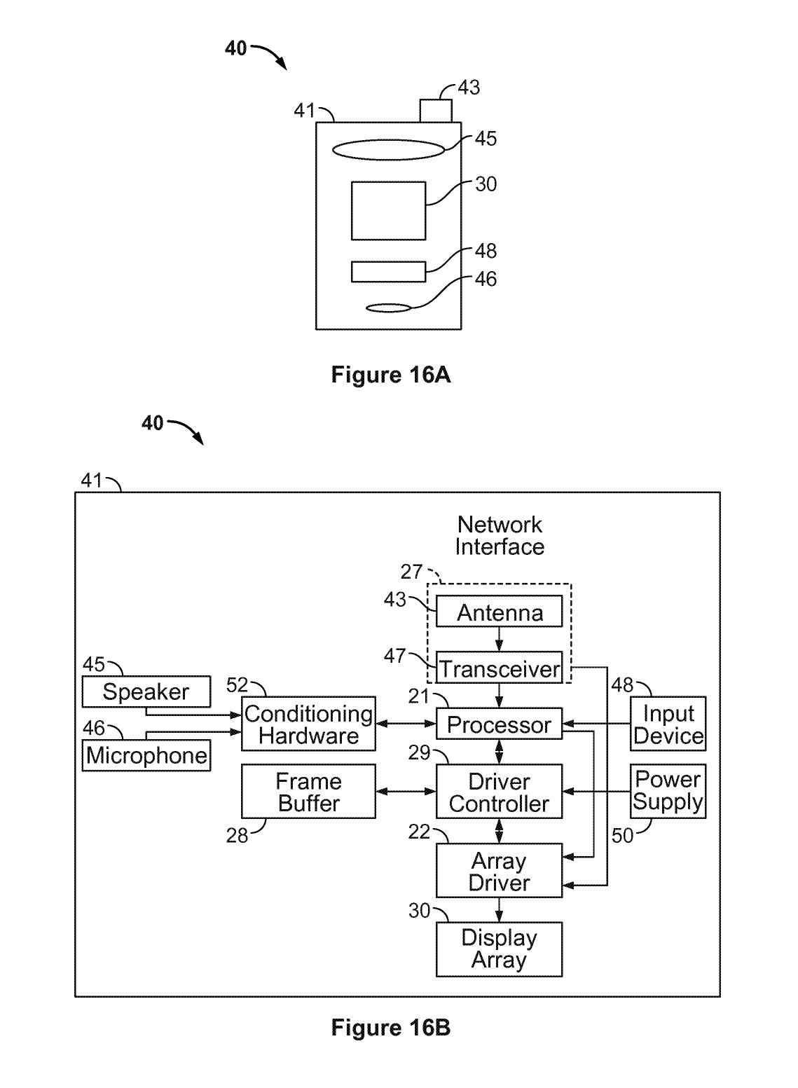

FIGS. 16A and 16B show examples of system block diagrams illustrating a display device 40 that includes a plurality of interferometric modulators. The display device 40 can be, for example, a cellular or mobile telephone. However, the same components of the display device 40 or slight variations thereof are also illustrative of various types of display devices such as televisions, e-readers and portable media players.

The display device 40 includes a housing 41, a display 30, an antenna 43, a speaker 45, an input device 48, and a microphone 46. The housing 41 can be formed from any of a variety of manufacturing processes, including injection molding, and vacuum forming. In addition, the housing 41 may be made from any of a variety of materials, including, but not limited to: plastic, metal, glass, rubber, and ceramic, or a combination thereof. The housing 41 can include removable portions (not shown) that may be interchanged with other removable portions of different color, or containing different logos, pictures, or symbols.

The display 30 may be any of a variety of displays, including a bi-stable or analog display, as described herein. The display 30 also can be configured to include a flat-panel display, such as plasma, EL, OLED, STN LCD, or TFT LCD, or a non-flat-panel display, such as a CRT or other tube device. In addition, the display 30 can include an interferometric modulator display, as described herein.

The components of the display device 40 are schematically illustrated in FIG. 16B. The display device 40 includes a housing 41 and can include additional components at least partially enclosed therein. For example, the display device 40 includes a network interface 27 that includes an antenna 43 which is coupled to a transceiver 47. The transceiver 47 is connected to a processor 21, which is connected to conditioning hardware 52. The conditioning hardware 52 may be configured to condition a signal (e.g., filter a signal). The conditioning hardware 52 is connected to a speaker 45 and a microphone 46. The processor 21 is also connected to an input device 48 and a driver controller 29. The driver controller 29 is coupled to a frame buffer 28, and to an array driver 22, which in turn is coupled to a display array 30. A power supply 50 can provide power to all components as required by the particular display device 40 design.

The network interface 27 includes the antenna 43 and the transceiver 47 so that the display device 40 can communicate with one or more devices over a network. The network interface 27 also may have some processing capabilities to relieve, e.g., data processing requirements of the processor 21. The antenna 43 can transmit and receive signals. In some implementations, the antenna 43 transmits and receives RF signals according to the IEEE 16.11 standard, including IEEE 16.11(a), (b), or (g), or the IEEE 802.11 standard, including IEEE 802.11a, b, g or n. In some other implementations, the antenna 43 transmits and receives RF signals according to the BLUETOOTH standard. In the case of a cellular telephone, the antenna 43 is designed to receive code division multiple access (CDMA), frequency division multiple access (FDMA), time division multiple access (TDMA), Global System for Mobile communications (GSM), GSM/General Packet Radio Service (GPRS), Enhanced Data GSM Environment (EDGE), Terrestrial Trunked Radio (TETRA), Wideband-CDMA (W-CDMA), Evolution Data Optimized (EV-DO), 1xEV-DO, EV-DO Rev A, EV-DO Rev B, High Speed Packet Access (HSPA), High Speed Downlink Packet Access (HSDPA), High Speed Uplink Packet Access (HSUPA), Evolved High Speed Packet Access (HSPA+), Long Term Evolution (LTE), AMPS, or other known signals that are used to communicate within a wireless network, such as a system utilizing 3G or 4G technology. The transceiver 47 can pre-process the signals received from the antenna 43 so that they may be received by and further manipulated by the processor 21. The transceiver 47 also can process signals received from the processor 21 so that they may be transmitted from the display device 40 via the antenna 43.

In some implementations, the transceiver 47 can be replaced by a receiver. In addition, the network interface 27 can be replaced by an image source, which can store or generate image data to be sent to the processor 21. The processor 21 can control the overall operation of the display device 40. The processor 21 receives data, such as compressed image data from the network interface 27 or an image source, and processes the data into raw image data or into a format that is readily processed into raw image data. The processor 21 can send the processed data to the driver controller 29 or to the frame buffer 28 for storage. Raw data typically refers to the information that identifies the image characteristics at each location within an image. For example, such image characteristics can include color, saturation, and gray-scale level.

The processor 21 can include a microcontroller, CPU, or logic unit to control operation of the display device 40. The conditioning hardware 52 may include amplifiers and filters for transmitting signals to the speaker 45, and for receiving signals from the microphone 46. The conditioning hardware 52 may be discrete components within the display device 40, or may be incorporated within the processor 21 or other components.

The driver controller 29 can take the raw image data generated by the processor 21 either directly from the processor 21 or from the frame buffer 28 and can re-format the raw image data appropriately for high speed transmission to the array driver 22. In some implementations, the driver controller 29 can re-format the raw image data into a data flow having a raster-like format, such that it has a time order suitable for scanning across the display array 30. Then the driver controller 29 sends the formatted information to the array driver 22. Although a driver controller 29, such as an LCD controller, is often associated with the system processor 21 as a stand-alone Integrated Circuit (IC), such controllers may be implemented in many ways. For example, controllers may be embedded in the processor 21 as hardware, embedded in the processor 21 as software, or fully integrated in hardware with the array driver 22.

The array driver 22 can receive the formatted information from the driver controller 29 and can re-format the video data into a parallel set of waveforms that are applied many times per second to the hundreds, and sometimes thousands (or more), of leads coming from the display's x-y matrix of pixels.

In some implementations, the driver controller 29, the array driver 22, and the display array 30 are appropriate for any of the types of displays described herein. For example, the driver controller 29 can be a conventional display controller or a bi-stable display controller (e.g., an IMOD controller). Additionally, the array driver 22 can be a conventional driver or a bi-stable display driver (e.g., an IMOD display driver). Moreover, the display array 30 can be a conventional display array or a bi-stable display array (e.g., a display including an array of IMODs). In some implementations, the driver controller 29 can be integrated with the array driver 22. Such an implementation is common in highly integrated systems such as cellular phones, watches and other small-area displays.

In some implementations, the input device 48 can be configured to allow, e.g., a user to control the operation of the display device 40. The input device 48 can include a keypad, such as a QWERTY keyboard or a telephone keypad, a button, a switch, a rocker, a touch-sensitive screen, or a pressure- or heat-sensitive membrane. The microphone 46 can be configured as an input device for the display device 40. In some implementations, voice commands through the microphone 46 can be used for controlling operations of the display device 40.

The power supply 50 can include a variety of energy storage devices as are well known in the art. For example, the power supply 50 can be a rechargeable battery, such as a nickel-cadmium battery or a lithium-ion battery. The power supply 50 also can be a renewable energy source, a capacitor, or a solar cell, including a plastic solar cell or solar-cell paint. The power supply 50 also can be configured to receive power from a wall outlet.

In some implementations, control programmability resides in the driver controller 29 which can be located in several places in the electronic display system. In some other implementations, control programmability resides in the array driver 22. The above-described optimization may be implemented in any number of hardware and/or software components and in various configurations.

The various illustrative logics, logical blocks, modules, circuits and algorithm steps described in connection with the implementations disclosed herein may be implemented as electronic hardware, computer software, or combinations of both. The interchangeability of hardware and software has been described generally, in terms of functionality, and illustrated in the various illustrative components, blocks, modules, circuits and steps described above. Whether such functionality is implemented in hardware or software depends upon the particular application and design constraints imposed on the overall system.

The hardware and data processing apparatus used to implement the various illustrative logics, logical blocks, modules and circuits described in connection with the aspects disclosed herein may be implemented or performed with a general purpose single- or multi-chip processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, or, any conventional processor, controller, microcontroller, or state machine. A processor also may be implemented as a combination of computing devices, e.g., a combination of a DSP and a microprocessor, a plurality of microprocessors, one or more microprocessors in conjunction with a DSP core, or any other such configuration. In some implementations, particular steps and methods may be performed by circuitry that is specific to a given function.

In one or more aspects, the functions described may be implemented in hardware, digital electronic circuitry, computer software, firmware, including the structures disclosed in this specification and their structural equivalents thereof, or in any combination thereof. Implementations of the subject matter described in this specification also can be implemented as one or more computer programs, i.e., one or more modules of computer program instructions, encoded on a computer storage media for execution by, or to control the operation of, data processing apparatus.

Various modifications to the implementations described in this disclosure may be readily apparent to those having ordinary skill in the art, and the generic principles defined herein may be applied to other implementations without departing from the spirit or scope of this disclosure. Thus, the claims are not intended to be limited to the implementations shown herein, but are to be accorded the widest scope consistent with this disclosure, the principles and the novel features disclosed herein. The word “exemplary” is used exclusively herein to mean “serving as an example, instance, or illustration.” Any implementation described herein as “exemplary” is not necessarily to be construed as preferred or advantageous over other implementations. Additionally, a person having ordinary skill in the art will readily appreciate, the terms “upper” and “lower” are sometimes used for ease of describing the figures, and indicate relative positions corresponding to the orientation of the figure on a properly oriented page, and may not reflect the proper orientation of the IMOD as implemented.

Certain features that are described in this specification in the context of separate implementations also can be implemented in combination in a single implementation. Conversely, various features that are described in the context of a single implementation also can be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. Further, the drawings may schematically depict one more example processes in the form of a flow diagram. However, other operations that are not depicted can be incorporated in the example processes that are schematically illustrated. For example, one or more additional operations can be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

What is claimed is:

1. An electromechanical systems varactor comprising:
a substrate;
a first metal layer overlying the substrate, the first metal layer including a first bias electrode;
a member suspended over the first metal layer, the member including:
a dielectric beam, and
a second metal layer, the second metal layer including a first radio frequency electrode and a ground electrode, the member and the first metal layer defining a first air gap; and
a third metal layer over the member, the third metal layer including a second bias electrode, the third metal layer and the member defining a second air gap,
wherein the member includes a plane of symmetry substantially parallel to a plane containing the first bias electrode.

2. The electromechanical systems varactor of claim 1, wherein the second metal layer is embedded in the dielectric beam.

3. The electromechanical systems varactor of claim 1, wherein the first radio frequency electrode includes a first layer and a second layer, wherein the ground electrode includes a first layer and a second layer, wherein the first layer of the first radio frequency electrode and the first layer of the ground electrode are exposed to the first air gap, wherein the second layer of the first radio frequency electrode and the second layer of the ground electrode are exposed to the second air gap, wherein the first layer and the second layer of the first radio frequency electrode are coupled to each other by a first conductive material filling a first via through the dielectric beam, and wherein the first layer and the second layer of the ground electrode are coupled to each other by a second conductive material filling a second via through the dielectric beam.

4. The electromechanical systems varactor of claim 1, wherein the member is configured to mechanically move into the first air gap in response to a first direct current voltage received by the first bias electrode, and wherein the member is configured to mechanically move into the second air gap in response to a second direct current voltage received by the second bias electrode.

5. The electromechanical systems varactor of claim 1, further comprising:
a non-planarized dielectric layer on the third metal layer.

6. The electromechanical systems varactor of claim 1, further comprising:
a first dielectric layer on the first metal layer, wherein the first dielectric layer is exposed to the first air gap, and wherein the first dielectric layer is configured to prevent electrical contact between the first metal layer and the second metal layer; and
a second dielectric layer on the third metal layer, wherein the second dielectric layer is exposed to the second air gap, and wherein the second dielectric layer is configured to prevent electrical contact between the third metal layer and the second metal layer.

7. The electromechanical systems varactor of claim 1, wherein the first metal layer further includes a second radio frequency electrode.

8. The electromechanical systems varactor of claim 7, wherein a capacitance between the first radio frequency electrode and the second radio frequency electrode varies depending on a distance between the first and the second radio frequency electrodes.

9. The electromechanical systems varactor of claim 7, wherein the first bias electrode and the second radio frequency electrode are coplanar.

10. The electromechanical systems varactor of claim 1, wherein the first bias electrode and the first radio frequency electrode are non-coplanar.

11. The electromechanical systems varactor of claim 1, wherein the third metal layer further includes a second radio frequency electrode.

12. The electromechanical systems varactor of claim 11, wherein a capacitance between the first radio frequency electrode and the second radio frequency electrode varies depending on a distance between the first and the second radio frequency electrodes.

13. The electromechanical systems varactor of claim 11, further comprising:
a non-planarized first dielectric layer on the first metal layer, wherein the non-planarized first dielectric layer is exposed to the first air gap.

14. A system comprising the electromechanical systems varactor of claim 1, the system further comprising:
a display;
a processor that is configured to communicate with the display, the processor being configured to process image data; and
a memory device that is configured to communicate with the processor.

15. The system of claim 14, further comprising:
a driver circuit configured to send at least one signal to the display; and
a controller configured to send at least a portion of the image data to the driver circuit.

16. The system of claim 14, further comprising:
an image source module configured to send the image data to the processor.

17. The system of claim 16, wherein the image source module includes at least one of a receiver, transceiver, and transmitter.

18. The system of claim 14, further comprising:
an input device configured to receive input data and to communicate the input data to the processor.

19. An electromechanical systems varactor comprising:
a substrate;
a first metal layer overlying the substrate, the first metal layer including a first bias electrode;
a member suspended over the first metal layer, the member including:
a dielectric beam, and
a second metal layer, the second metal layer including a first radio frequency electrode and a ground electrode, the first radio frequency electrode and the ground electrode being electrically isolated from each other; and
a third metal layer over the member, the third metal layer including a second bias electrode,
wherein the member includes a plane of symmetry substantially parallel to a plane containing the first bias electrode.

20. The electromechanical systems varactor of claim 19, wherein the second metal layer is embedded in the dielectric beam.

21. The electromechanical systems varactor of claim 19, wherein the first radio frequency electrode includes a first layer and a second layer, wherein the ground electrode includes a first layer and a second layer, wherein the first layer of the first radio frequency electrode and the first layer of the ground electrode are exposed to the first air gap, wherein the second layer of the first radio frequency electrode and the second layer of the ground electrode are exposed to the second air gap, wherein the first layer and the second layer of the first radio frequency electrode are coupled to each other by a first conductive material filling a first via through the dielectric beam, and wherein the first layer and the second layer of the ground electrode are coupled to each other by a second conductive material filling a second via through the dielectric beam.

22. The electromechanical systems varactor of claim 18, wherein the first metal layer further includes a second radio frequency electrode.

23. The electromechanical systems varactor of claim 22, wherein a capacitance between the first radio frequency electrode and the second radio frequency electrode varies depending on a distance between the first and the second radio frequency electrodes.

24. A method of fabricating an electromechanical systems varactor comprising:
forming a first metal layer on a substrate;
forming a first sacrificial layer on the first metal layer;
forming a member on the first sacrificial layer, the member including a dielectric beam, a first radio frequency electrode, and a ground electrode;
forming a second sacrificial layer on the member;
forming a second metal layer on the second sacrificial layer; and
removing the first and the second sacrificial layers, wherein the dielectric beam, the first radio frequency electrode, and the ground electrode include a plane of symmetry substantially parallel to a plane containing the first metal layer.

25. The method of claim 24, wherein forming the member includes:
forming a first dielectric layer on the first sacrificial layer;
forming a third metal layer on the first dielectric layer;
forming the first radio frequency electrode and the ground electrode from the third metal layer; and
forming a second dielectric layer on the third metal layer, wherein the first dielectric layer and the second dielectric layer form the dielectric beam.

26. The method of claim 24, wherein forming the member includes:
forming a third metal layer on the first sacrificial layer;
forming a bottom layer of the first radio frequency electrode and a bottom layer of the ground electrode from the third metal layer;
forming a dielectric layer on the third metal layer;
etching first vias and second vias in the dielectric layer;
forming a fourth metal layer on the dielectric layer, including filling the first vias and second vias with the fourth metal layer;
forming a top layer of the first radio frequency electrode and a top layer of the ground electrode from the fourth metal layer, wherein the first vias electrically couple the bottom layer and the top layer of the first radio frequency electrode, wherein the second vias electrically couple the bottom layer and the top layer of the ground electrode, and wherein the dielectric layer forms the dielectric beam.

27. The method of claim 24, further comprising:
forming a first bias electrode and a second radio frequency electrode from the first metal layer.

28. The method of claim 24, further comprising:
forming a first bias electrode and a second radio frequency electrode from the second metal layer.
